(19) United States
(12) Patent Application Publication
(10) Pub. No.: US 2026/0324053 A1
(43) Pub. Date: Oct. 15, 2026

(54) PLANAR GATE VERTICAL SILICON CARBIDE BASED SEMICONDUCTOR DEVICES WITH IMPROVED RECOVERY CHARACTERISTICS AND RUGGEDNESS

(71) Applicant: Wolfspeed, Inc., Durham, NC (US)

(72) Inventors: Jae-Hyung Park, Apex, NC (US); Joohyung Kim, Cary, NC (US); Sei-Hyung Ryu, Cary, NC (US)

(21) Appl. No.: 19/570,747

(22) Filed: Mar. 18, 2026

Related U.S. Application Data
(63) Continuation-in-part of application No. 19/179,393, filed on Apr. 15, 2025.

(51) Int. Cl. H10D 84/00; H10D 8/00; H10D 8/01; H10D 8/50; H10D 30/01; H10D 30/66; H10D 62/10; H10D 62/60; H10D 62/832; H10D 64/23; H10D 84/01

(52) U.S. Cl. CPC H10D 84/141; H10D 8/50; H10D 30/66; H10D 62/107; H10D 62/60; H10D 8/01; H10D 8/411; H10D 30/0291; H10D 62/127; H10D 62/8325; H10D 64/2527; H10D 84/0109; H10D 84/143

(57) ABSTRACT

A semiconductor device such as a MOSFET or IGBT comprises a semiconductor layer structure that comprises a drift layer and a plurality of well regions in the drift layer, the well regions extending to an upper surface of the semiconductor layer structure. The drift layer comprises a first region and a second region that has a higher peak doping concentration type than the first region. The second region of the drift layer comprises an implanted region and extends between adjacent well regions and underneath the well regions. The second region of the drift layer also comprises a plurality of openings, and the first region of the drift layer is exposed through the openings in the second region of the drift layer.

### CROSS-REFERENCE TO RELATED APPLICATION

The present application claims priority under 35 U.S.C. § 120 as a continuation-in-part of U.S. patent application Ser. No. 19/179,393, filed Apr. 15, 2025, the entire content of which is incorporated herein by reference as if set forth in its entirety.

### FIELD

The present invention relates to semiconductor devices and, more particularly, to power semiconductor devices and to methods of fabricating such devices.

### BACKGROUND

The Metal Oxide Semiconductor Field Effect Transistor (“MOSFET”) is a well-known type of semiconductor transistor that may be used as a switch.

A MOSFET is a three terminal device that has gate, drain and source terminals and a semiconductor body. The semiconductor body is referred to herein as a “semiconductor structure” and may include one or more semiconductor layers/regions. A source region and a drain region that each have a first conductivity type are formed in the semiconductor structure and are separated from each other by a channel region that has a second conductivity type. The source region is electrically connected to the source terminal and the drain region is electrically connected to the drain terminal. A gate electrode is provided adjacent the channel region and separated from the channel region by a thin gate dielectric layer such as a thin oxide layer. A MOSFET may be turned on or off by setting a bias voltage that is applied to the gate electrode to be above or below a threshold value. When a MOSFET is turned on (i.e., it is in its “on-state”), current is conducted through the channel region between the source and drain regions, thereby allowing current to flow between the source and drain terminals. When the bias voltage is reduced below the threshold level, the current ceases to conduct through the channel region.

An n-type MOSFET has source and drain regions that have n-type (electron) conductivity and a channel region that has p-type (hole) conductivity. An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has p-type source and drain regions and an n-type channel region, and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity. In other words, as used herein, the terms first conductivity type and second conductivity type refer to two different conductivity types.

Because the gate electrode of a MOSFET is insulated from the channel region by the gate dielectric layer, minimal gate current is required to maintain the MOSFET in its on-state or to switch the MOSFET between its off-state and its on-state. Because the gate forms a capacitor with the channel region, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. The base current of the BJT is supplied through the channel of the MOSFET, thereby allowing a simplified external drive circuit (since the drive circuit only charges and discharges the gate electrode of the MOSFET).

Power MOSFETs and other power semiconductor devices are often formed in wide band-gap semiconductor materials (herein, the term “wide band-gap semiconductor” encompasses any semiconductor having a band-gap of at least 1.4 eV) such as silicon carbide. Silicon carbide which has a number of advantageous characteristics for power semiconductor devices including, for example, a high electric field breakdown strength, high thermal conductivity, high electron mobility, high melting point and high-saturated electron drift velocity

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate terminals may be on the top surface of the semiconductor layer structure and the drain terminal may be on the bottom surface of the semiconductor layer structure). The semiconductor structure may or may not include an underlying substrate such as a growth substrate. Vertical power semiconductor devices can typically block higher voltage levels than lateral power semiconductor devices.

Vertical power MOSFETs can have a planar gate design in which the gate electrodes are formed on top of the semiconductor structure or, alternatively, may have a gate trench design in which the gate electrodes are formed within gate trenches in the semiconductor structure. With the planar gate design, the channel region of each unit cell transistor is typically horizontally disposed underneath the gate electrode. In contrast, in gate trench devices, the channels are typically vertically disposed channels that are formed in sidewalls of the gate trenches.

The semiconductor structure of a power semiconductor device typically includes an “active region” in which one or more functional semiconductor devices are formed. The active region acts as a main junction for blocking voltage during reverse bias (off-state) operation and providing current flow during forward bias (on-state) operation. Power semiconductor devices may also have edge termination structures such as, for example, guard rings or junction termination extensions. These edge termination structures are formed in a termination region of the semiconductor structure that is adjacent (and typically surrounding) the active region. The edge termination structures may, among other things, reduce electric field crowding effects that can occur at the outer edges of a power semiconductor device. Typically, multiple power semiconductor devices are formed in/on a common wafer, and each power semiconductor device will have its own edge termination structure. After the wafer is fully processed, the processed wafer may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

FIGS. 1A and 1B are a schematic plan (top) view and a schematic cross-sectional view of a small portion of an active region of a conventional vertical silicon carbide power MOSFET 1 that has a planar gate structure. In the plan view of FIG. 1A, the upper dielectric layers, the gate electrodes and the source metallization are omitted to show the upper surface of the semiconductor structure 50 of power MOSFET 1. The dashed boxes in FIG. 1A show where gate electrodes are formed on an upper surface of the semiconductor structure 50 (with a gate dielectric layer separating the gate electrode from the semiconductor structure 50), and the dotted boxes show where the source metallization extends through openings defined between adjacent gate electrodes to contact the semiconductor structure 50. FIG. 1B is a schematic cross-sectional diagram taken along the line 1B-1B of FIG. 1A with the gate electrodes and various upper metallization and dielectric layers of the power MOSFET that are omitted in FIG. 1A added for context.

As shown in FIGS. 1A-1B, power MOSFET 1 includes a heavily-doped n-type (n+) silicon carbide semiconductor substrate 10. A lightly-doped n-type (n⁻) silicon carbide drift layer 20 is provided on the upper surface of the substrate 10. In the depicted device, the drift layer 20 includes a first region 22 that has a first peak doping concentration and a second region 24 that is on an upper surface of the first region 22. The second region 24 has a second peak doping concentration that is higher than the first peak doping concentration. In other cases, the drift layer 20 may have a constant doping density and hence may not be divided into the first and second regions 22, 24. The drift layer 20 may also be referred to herein as a drift region 20. A plurality of p-type well implant regions 30 are formed on/in upper portions of the n-type silicon carbide drift layer 20. Each well implant region 30 comprises a moderately doped p-type well region 32 (for n-type MOSFETs such as MOSFET 1, these well regions are also referred to herein as “p-wells”) and a heavily doped p-type well contact region 34. Each well contact region 34 is in an upper middle portion of an associated well implant region 30, and a bottom surface of each well contact region 34 contacts an associated p-well 32. The well implant regions 30 are typically formed by ion implantation. Channel regions 36 are formed in the upper outer portion of each p-well 32. A pair of heavily-doped (n⁺) n-type silicon carbide source regions 40 are formed in upper portions of each well implant region 30. The portions of the drift layer 20 that are in between adjacent well implant regions 30 are referred to as JFET regions. The second region 24 of the drift layer 20 is provided in between adjacent well implant regions 30 and also extends underneath the well implant regions 30. The n-type silicon carbide substrate 10, n-type silicon carbide drift layer 20, the well implant regions 30, and the n-type source regions 40 together comprise the semiconductor layer structure 50 of the MOSFET 1.

Referring to FIG. 1B, a plurality of gate oxide layers 60 are formed on the upper surface of the semiconductor structure 50, and a plurality of gate electrodes 62 are formed on the respective gate oxide layers 60 opposite the semiconductor structure 50. A plurality of intermetal dielectric patterns 64 cover the respective gate electrodes 62. Openings are defined in between adjacent intermetal dielectric patterns 64 that expose the upper surface of the semiconductor structure 50. A source metallization 90 is formed on the intermetal dielectric patterns 64 and within the openings in the intermetal dielectric pattern 64 so as to contact the heavily-doped n-type source regions 40 and the heavily-doped p-type well contact regions 34. A drain contact 92 is formed on the lower surface of the substrate 10.

The p-type channel regions 36 that are formed in the upper portions of the p-wells 32 electrically connect the n-type source regions 40 to the second region 24 of the drift layer 20 when a sufficient gate bias voltage is applied to the gate electrodes 62. When such a gate bias voltage is applied to the gate electrodes 62 (through the gate terminal of the MOSFET), current may flow from the source metallization 90 (which serves as or is electrically connected to the source terminal of the MOSFET) to the n-type source regions 40 through the channel regions 36 to the second region 24 of the drift layer 20. The current flows from the second region 24 of the drift layer 20 to the first region 22 of the drift layer 20 and into the substrate 10 and the drain contact 92, which serves as or is electrically connected to the drain terminal of the MOSFET 1.

Transistors used in power switching circuitry such as power MOSFET 1 generally need to be capable of conducting current bidirectionally. Accordingly, an anti-parallel diode is provided in conjunction with the transistor to allow bidirectional current flow. An anode of the anti-parallel diode is coupled to a drain of the MOSFET 1 and a cathode of the anti-parallel diode is coupled to a source of the MOSFET 1. This allows current to flow from the drain to the source in the MOSFET during a forward conduction mode of operation and from the source to the drain via the anti-parallel diode in a reverse conduction mode of operation. When switching between conducting and blocking, performance characteristics of the anti-parallel diode will determine the speed at which such a transition can occur and the switching losses that occur. It is generally desirable to minimize both the transition time between modes of operation and the switching losses.

While an external diode may be used as the anti-parallel diode, the same result can also be achieved using one or more built-in body diodes that are formed in the semiconductor structure 50. In particular, as shown in FIG. 1B, body diodes 70 are formed between the source metallization 90 and the drain contact 92. Using body diodes 70 to allow bidirectional current conduction saves space by foregoing the need for an external diode. However, the body diodes 70 may not be optimized for switching, which may result in increased switching times and/or increased switching losses.

### SUMMARY

Pursuant to some embodiments of the present invention, semiconductor devices are provided that comprise a semiconductor layer structure that comprises a drift layer having a first conductivity type that comprises a first region that has a first peak doping concentration and a second region that has a second peak doping concentration type that is greater than the first peak doping concentration and a plurality of well regions having a second conductivity type, the well regions extending to an upper surface of the semiconductor layer structure. The second region of the drift layer comprises an implanted region that is between adjacent well regions and underneath at least portions of the well regions. The second region of the drift layer also comprises a plurality of openings, and the first region of the drift layer is in the openings in the second region of the drift layer.

In some embodiments, the second region of the drift layer may be on top of the first region of the drift layer. In some embodiments, the first region of the drift layer may extend into the openings in the second region of the drift layer. In some embodiments, each well region may be part of a respective well implant region that has the second conductivity type, and each well implant region may further comprise a respective well contact region that has the second conductivity type, the well contact regions having higher peak doping concentration than the well regions. In some embodiments, each well contact region may be above and vertically overlapping a respective one of the openings in the second region of the drift layer. In some embodiments, a first of the well contact regions may be within a first of the well regions and may vertically overlap a first of the openings in the second region of the drift layer.

In some embodiments, a first area of a bottom of the first of the openings may be greater than a second area of a bottom surface of the first of the well contact regions. In other embodiments, a first area of a bottom of the first of the openings may be less than a second area of a bottom surface of the first of the well contact regions. In some embodiments, the first of the well regions may extend deeper into the semiconductor layer structure than the first of the well contact regions. In some embodiments, the first of the well contact regions may extend deeper into the semiconductor layer structure than the first of the well regions. In some embodiments, the first of the well contact regions may directly contact the first region of the drift layer. In some embodiments, the first of the well regions may also directly contact the first region of the drift layer.

In some embodiments, the semiconductor device may further comprise a gate oxide layer on an upper surface of the semiconductor layer structure and a gate electrode on the gate oxide layer opposite the semiconductor layer structure, and a bottom surface of the gate electrode may be above an uppermost surface of the semiconductor layer structure.

In some embodiments, a portion of the drift layer that directly contacts a lower surface of a first of the well implant regions may comprise a first portion that is implanted with n-type dopants and a second portion that is not implanted with n-type dopants.

In some embodiments, the first region of the drift layer may comprise a plurality of upwardly-extending protrusions that are positioned underneath the respective well implant regions. In some embodiments, the upwardly-extending protrusions are not implanted with first conductivity type dopants.

In some embodiments, the second region of the drift layer may directly contact a bottom of the well region and the first region of the drift layer may directly contact a bottom of the well contact region. In some embodiments, the semiconductor device may be a silicon carbide based MOSFET.

Pursuant to further embodiments of the present invention, semiconductor devices are provided that comprise a semiconductor layer structure that comprises a drift layer having a first conductivity type and a plurality of well implant regions, the well implant regions extending to an upper surface of the semiconductor layer structure and each well implant region comprising a well region having the second conductivity type and a first peak doping concentration and a well contact region having the second conductivity type and a second peak doping concentration, where the second peak doping concentration exceeds the first peak doping concentration. The drift layer comprises an implanted portion that is implanted with n-type dopants and an un-implanted portion that is not implanted with n-type dopants, where both the implanted portion and the un-implanted portion directly contact a first of the well implant regions.

In some embodiments, the un-implanted portion of the drift layer may have a third peak doping concentration and the implanted portion of the drift layer may have a fourth peak doping concentration type that is greater than the third peak doping concentration. In some embodiments, each well contact region may directly contact the un-implanted portion of the drift layer. In some embodiments, the un-implanted portion of the drift layer may also directly contact a bottom of each well region.

In some embodiments, the semiconductor device may further comprise a gate oxide layer on an upper surface of the semiconductor layer structure and a gate electrode on the gate oxide layer opposite the semiconductor layer structure, and a bottom surface of the gate electrode may be above an uppermost surface of the semiconductor layer structure.

In some embodiments, the un-implanted portion of the drift layer may comprise a plurality of upwardly-extending protrusions that are positioned underneath the respective well implant regions.

Pursuant to additional embodiments of the present invention, semiconductor devices are provided that comprise a semiconductor layer structure that comprises a drift layer having a first conductivity type and a plurality of well implant regions, the well implant regions extending to an upper surface of the semiconductor layer structure and each well implant region comprising a well region having the second conductivity type and a first peak doping concentration and a well contact region having the second conductivity type and a second peak doping concentration, where the second peak doping concentration exceeds the first peak doping concentration. A first region of the drift layer that directly contacts a middle portion of a bottom of a first of the well implant regions has a first doping concentration and a second region of the drift layer that directly contacts an outer portion of the bottom of the first of the well implant regions has a second doping concentration that is greater than the first doping concentration.

In some embodiments, the second region of the drift layer may be on top of the first region of the drift layer. In some embodiments, the first region of the drift layer may not be implanted with first conductivity type dopants and the second region of the drift layer may be implanted with first conductivity type dopants.

In some embodiments, the first region of the drift layer may directly contact each well contact region. In some embodiments, the first region of the drift layer may also directly contact a bottom of each well region.

In some embodiments, the second region of the drift layer may comprise a plurality of openings, and the first region of the drift layer may extend into the openings in the second region of the drift layer. In some embodiments, each well contact region may be above and vertically overlapping a respective one of the openings in the second region of the drift layer.

In some embodiments, each well contact region may directly contact the first region of the drift layer.

In some embodiments, the semiconductor device may further comprise a gate oxide layer on an upper surface of the semiconductor layer structure and a gate electrode on the gate oxide layer opposite the semiconductor layer structure, and a bottom surface of the gate electrode is above an uppermost surface of the semiconductor layer structure.

Pursuant to yet further embodiments of the present invention, semiconductor devices are provided that comprise a semiconductor layer structure that comprises a drift layer having a first conductivity type that comprises a first region that has a first peak doping concentration and a second region that has a second peak doping concentration type that is greater than the first peak doping concentration and a plurality of well implant regions in an upper portion of the drift layer, the well implant regions extending to an upper surface of the semiconductor layer structure and each well implant region comprising a well region having the second conductivity type and a first peak doping concentration and a well contact region having the second conductivity type and a second peak doping concentration, where the second peak doping concentration exceeds the first peak doping concentration. The second region of the drift layer directly contacts bottom portions of at least some of the well regions and the first region of the drift layer directly contacts bottom portions of at least some of the well contact regions.

In some embodiments, the first region of the drift layer may comprise protrusions that extend upwardly through respective openings that are provided in the second region of the drift layer. In some embodiments, each well contact region may be above and vertically overlapping a respective one of the openings in the second region of the drift layer. In some embodiments, each well contact region may directly contact the first region of the drift layer.

In some embodiments, the second region of the drift layer may be on top of the first region of the drift layer.

In some embodiments, the first region of the drift layer may not be implanted with first conductivity type dopants and the second region of the drift layer may be implanted with first conductivity type dopants.

In some embodiments, the semiconductor device may further comprise a gate oxide layer on an upper surface of the semiconductor layer structure and a gate electrode on the gate oxide layer opposite the semiconductor layer structure, wherein a bottom surface of the gate electrode is above an uppermost surface of the semiconductor layer structure.

Pursuant to still further embodiments of the present invention, semiconductor devices are provided that comprise a semiconductor layer structure that comprises a drift layer having a first conductivity type that comprises a first region that has a first peak doping concentration and a second region that has a second peak doping concentration type that is greater than the first peak doping concentration and a plurality of well implant regions, the well implant regions extending to an upper surface of the semiconductor layer structure and each well implant region comprising a well region having the second conductivity type and a first peak doping concentration and a well contact region having the second conductivity type and a second peak doping concentration, where the second peak doping concentration exceeds the first peak doping concentration. The first region of the drift layer comprises a plurality of upwardly-extending protrusions that are positioned underneath the respective well implant regions.

In some embodiments, the second region of the drift layer may comprise a plurality of openings, and the upwardly-extending protrusions of the first region of the drift layer may extend into the respective openings in the second region of the drift layer. In some embodiments, the second region of the drift layer may be on top of the first region of the drift layer. In some embodiments, each well contact region may be above and vertically overlapping a respective one of the openings in the second region of the drift layer. In some embodiments, the first region of the drift layer may directly contact each well contact region. In some embodiments, the first region of the drift layer may also directly contact a bottom surface of each well region.

In some embodiments, the semiconductor device may further comprise a gate oxide layer on an upper surface of the semiconductor layer structure and a gate electrode on the gate oxide layer opposite the semiconductor layer structure, and a bottom surface of the gate electrode is above an uppermost surface of the semiconductor layer structure.

Pursuant to other embodiments of the present invention, methods of forming a semiconductor device are provided. Pursuant to these methods, a preliminary drift layer having a first conductivity type is formed on a substrate. First conductivity type dopants are implanted into the first preliminary drift layer using a first ion implantation mask and second conductivity type dopants are implanted into the preliminary drift layer using a second ion implantation mask to convert the preliminary drift layer into a drift layer that has a first region that is not implanted with first conductivity type dopants and a second region that is implanted with second conductivity dopants and to form a plurality of preliminary well implant regions in an upper portion of the drift layer, each preliminary well implant region having a second conductivity type.

In some embodiments, the method may further comprise implanting second conductivity type dopants into the preliminary well implant regions using a third ion implantation mask to convert each preliminary well implant region into a well implant region that comprises a well region having a first peak doping concentration and a well contact region having a second peak doping concentration that is greater than the first peak doping concentration.

In some embodiments, the second region of the drift layer may comprise a plurality of openings. In some embodiments, the first region of the drift layer may comprise a plurality of upwardly-extending protrusions.

In some embodiments, the upwardly-extending protrusions in the first region of the drift layer may extend into the respective openings in the second region of the drift layer.

Pursuant to further embodiments of the present invention, semiconductor devices are provided that comprise a semiconductor structure that comprises a drift region having a first conductivity type, a well region that has a second conductivity type on the drift region, a source region having the first conductivity type on the well region, and a well contact region having the second conductivity type on the well region, the well contact region having a higher doping concentration than the well region. A lower portion of the well contact region directly contacts a portion of the semiconductor structure that has the first conductivity type

In some embodiments, the semiconductor device may further comprise a gate dielectric layer on an upper surface of the semiconductor structure and a gate electrode on the gate dielectric layer opposite the semiconductor structure. In some embodiments, a channel region is provided in an upper portion of the well region and the well region directly contacts both the source region and the well contact region. In some embodiments, the semiconductor device may further comprise a source metallization on an upper surface of the semiconductor structure, where an upper surface of the well contact region directly contacts the source metallization.

In some embodiments, the lower portion of the well contact region directly contacts an electric field concentration region that has the first conductivity type, the electric field concentration region having a doping concentration that is greater than a doping concentration of the drift region. In some embodiments, the electric field concentration region extends deeper into the semiconductor structure than does the well region. In some embodiments, the doping concentration of the electric field concentration region is less than a doping concentration of the source region. In some embodiments, the well region extends deeper into the semiconductor structure than does the electric field concentration region, and the doping concentration of the electric field concentration region exceeds the doping concentration of the well region.

In some embodiments, the lower portion of the well contact region directly contacts the drift region. In some embodiments, the well contact region extends deeper into the semiconductor structure than does the well region. In some embodiments, an upper surface of the semiconductor structure includes a recess that extends into the well contact region, and the source metallization extends into the recess. In some embodiments, in a lateral cross-section of the semiconductor device, the lower portion of the well contact region includes a corner having an internal angle that is less than 90°.

In some embodiments, the semiconductor structure further comprises a current spreading layer that has the first conductivity type on the drift region, the current spreading layer having a doping concentration that is higher than a doping concentration of the drift region. In some embodiments, the lower portion of the well contact region directly contacts the current spreading layer. In some embodiments, the current spreading layer extends deeper into the semiconductor structure than does the well region.

In some embodiments, a lower portion of the well contact region directly contacts the well region. In some embodiments, the well region extends deeper into the semiconductor structure than does the well contact region.

In some embodiments, the well region includes a first lower corner and a second lower corner, where the second lower corner is closer to the well contact region than the first lower corner. In some embodiments, the second lower corner is a sharper corner than the first lower corner. In some embodiments, the semiconductor device is configured so that during reverse blocking operations the electric field level at the second lower corner is higher than the electric field level at the first lower corner.

Pursuant to additional embodiments of the present invention, semiconductor devices are provided that comprise a semiconductor structure that comprises a drift region having a first conductivity type, a well region having a second conductivity type on the drift region, a source region having the first conductivity type on the well region, and a well contact region having the second conductivity type on the well region, the well contact region having a higher doping concentration than the well region. in a lateral cross-section of the semiconductor device, the well region comprises a first lower corner at a first depth from an upper surface of the semiconductor structure and a second lower corner that is at a second depth from the upper surface of the semiconductor structure that exceeds the first depth. Additionally, the second lower corner is sharper than the first lower corner.

In some embodiments, the first lower corner and the second lower corner each have an interior angle that is less than 180°.

In some embodiments, a first portion of the well region that vertically overlaps a center of the well contact region in a lateral direction extends deeper into the semiconductor structure than does a second portion of the well region that vertically overlaps a center of the source region in the lateral direction. In some embodiments, the semiconductor device may further comprise a source metallization on an upper surface of the semiconductor structure, where an upper surface of the well contact region directly contacts the source metallization. In some embodiments, an upper surface of the semiconductor structure includes a recess that extends into the well contact region, and the source metallization extends into the recess.

In some embodiments, the well region is a first well region and the source region is a first source region, the semiconductor structure further comprising a second well region that has the second conductivity type on the drift region and a second source region that has the first conductivity type on the second well region and a JFET region that has the first conductivity type underneath the gate electrode and laterally in between the first and second well regions, and wherein the first lower corner and the second lower corner abut the JFET region.

In some embodiments, the semiconductor device is configured so that during reverse blocking operations the electric field level at the second lower corner is higher than the electric field level at the first lower corner.

In some embodiments, the first lower corner is a rounded corner having a first radius of curvature and the second lower corner is a rounded corner having a second radius of curvature that is smaller than the first radius of curvature.

In some embodiments, the second lower corner is a lower corner of a downwardly-extending shield region of the well region, and the source region does not vertically overlap the shield region.

Pursuant to still further embodiments of the present invention, semiconductor devices are provided that comprise a semiconductor structure that comprises a drift region having a first conductivity type, a well implant region having a second conductivity type on the drift region, the well implant region including at least a first well region and a well contact region that has a higher doping concentration than the first well region, a source region having the first conductivity type on the first well region and directly contacting the well contact region, and a selectively implanted electric field concentration region having the first conductivity type underneath the well contact region and directly contacting a sidewall of the first well region.

In some embodiments, the electric field concentration region has a higher doping concentration than the drift region. In some embodiments, the semiconductor structure further comprises a second well implant region that has the second conductivity type on the drift region, a second source region that has the first conductivity type in the second well implant region, and a JFET region that has the first conductivity type in between the first well implant region and the second well implant region, wherein the electric field concentration region has a higher doping concentration than the JFET region. In some embodiments, the semiconductor device may further comprise a gate electrode on the semiconductor structure, the gate electrode vertically overlapping the JFET region and the first and second well implant regions. In some embodiments, the first well region includes a first lower corner that faces the JFET region and a second lower corner that faces away from the JFET region. In some embodiments, the second lower corner is sharper than the first lower corner. In some embodiments, the semiconductor device is configured so that during reverse blocking operations the electric field level at the second lower corner is higher than the electric field level at the first lower corner.

In some embodiments, a lower portion of the well contact region directly contacts the electric field concentration region. In some embodiments, the lower portion of the well contact region also directly contacts the first well region.

In some embodiments, the electric field concentration region has a doping concentration that is greater than a doping concentration of the drift region.

In some embodiments, the electric field concentration region extends deeper into the semiconductor structure than does the first well region. In some embodiments, the doping concentration of the electric field concentration region is less than a doping concentration of the source region.

In some embodiments, the first well region extends deeper into the semiconductor structure than does the electric field concentration region, and the doping concentration of the electric field concentration region exceeds the doping concentration of the first well region

Pursuant to other embodiments of the present invention, semiconductor devices are provided that comprise a semiconductor structure that comprises a drift region having a first conductivity type, a well region that has a second conductivity type on the drift region, a source region having the first conductivity type on the well region, and a well contact region that has the second conductivity type and a higher doping concentration than the well region on the well region. The well contact region extends further into the semiconductor structure than does the well region.

In some embodiments, the semiconductor device may further comprise a source metallization on an upper surface of the semiconductor structure, where an upper surface of the well contact region directly contacts the source metallization. In some embodiments, an upper surface of the semiconductor structure includes a recess that extends into the well contact region, and the source metallization extends into the recess.

In some embodiments, a lower portion of the well contact region directly contacts the drift region.

In some embodiments, in a lateral cross-section of the semiconductor device, a lower portion of the well contact region includes a corner having an internal angle that is less than 90°.

In some embodiments, the well region includes a first lower corner and the well contact region includes a second lower corner, where the second lower corner is a sharper corner than the first lower corner.

Pursuant to yet additional embodiments of the present invention, semiconductor devices are provided that comprise a semiconductor structure that comprises a drift region having a first conductivity type, a well implant region that has a second conductivity type on the drift region, a source region having the first conductivity type within the well implant region, where the well implant region comprises a well region and a well contact region that has a higher doping concentration than the well region. The semiconductor structure is configured so that avalanche currents primarily flow into a central portion of a lower surface of the well implant region.

In some embodiments, the semiconductor device may further comprise a gate dielectric layer on an upper surface of the semiconductor structure and a gate electrode on the gate dielectric layer opposite the semiconductor structure. In some embodiments, the semiconductor device may further comprise a source metallization on an upper surface of the semiconductor structure, where an upper surface of the well contact region directly contacts the source metallization. In some embodiments, the well contact region extends deeper into the semiconductor structure than does the well region. In some embodiments, an upper surface of the semiconductor structure includes a recess that extends into the well contact region, and the source metallization extends into the recess.

In some embodiments, the semiconductor structure further comprises an electric field concentration region that has the first conductivity type underneath the well contact region, the electric field concentration region having a doping concentration that is greater than a doping concentration of the drift region. In some embodiments, the well region extends deeper into the semiconductor structure than does the electric field concentration region, and the doping concentration of the electric field concentration region exceeds the doping concentration of the well region. In some embodiments, the electric field concentration region extends deeper into the semiconductor structure than does the well region.

In some embodiments, a lower portion of the well contact region directly contacts the drift region.

Pursuant to yet still other embodiments of the present invention, semiconductor devices are provided that comprise a semiconductor structure that comprises a drift region having a first conductivity type, a well region that has a second conductivity type on the drift region, a source region having the first conductivity type on the well region, and a well contact region that has the second conductivity type and a higher doping concentration than the well region on the well region and a gate electrode on the semiconductor structure. A lower corner of the well contact region that directly contacts a portion of the semiconductor structure that has the first conductivity type is sharper than a lower corner of the well region that is farthest from the well contact region.

In some embodiments, the lower portion of the well contact region directly contacts an electric field concentration region that has the first conductivity type, the electric field concentration region having a first conductivity type doping concentration that is greater than a doping concentration of the drift region. In some embodiments, the electric field concentration region extends deeper into the semiconductor structure than does the well region. In some embodiments, the well region extends deeper into the semiconductor structure than does the electric field concentration region, and the doping concentration of the electric field concentration region exceeds the doping concentration of the well region.

In some embodiments, the lower portion of the well contact region directly contacts the drift region. In some embodiments, the well contact region extends deeper into the semiconductor structure than does the well region.

In some embodiments, in a lateral cross-section of the semiconductor device, the lower portion of the well contact region includes a corner having an internal angle that is less than 90°.

In some embodiments, the semiconductor structure further comprises a current spreading layer that has the first conductivity type on the drift region, the current spreading layer having a doping concentration that is higher than a doping concentration of the drift region, and the lower portion of the well contact region directly contacts the current spreading layer.

In some embodiments, a lower portion of the well contact region directly contacts the well region.

In some embodiments, the semiconductor device is configured so that during reverse blocking operations the electric field level at the second lower corner is higher than the electric field level at the first lower corner.

Pursuant to still further embodiments of the present invention, semiconductor devices are provided that comprise a semiconductor structure that comprises a drift region having a first conductivity type, a well implant region that has a second conductivity type on the drift region, the well implant region comprising first and second well regions and a well contact region on the first and second well regions and having a higher doping concentration than the first and second well regions, and first and second source regions having the first conductivity type on the respective first and second well regions. The well contact region has a longitudinal axis that extends in a first direction and the first and second well regions are spaced apart from each other in a second direction that is perpendicular to the first direction, and the first and second well regions are spaced apart from each by a first distance in in a first region and are spaced apart from each other by a second distance in a second region, where the second distance is greater than the first distance.

In some embodiments, a width of the second well region in the second direction varies along a length of the second well region.

In some embodiments, a portion of the drift region is positioned in between portions of the first and second well regions.

In some embodiments, an electric field concentration region that has a first conductivity type and a higher doping concentration than the drift region is positioned in between portions of the first and second well regions.

In some embodiments, the well contact region extends deeper into the semiconductor structure in between portions of the first and second well regions.

In some embodiments, a portion of the drift region is positioned in between portions of the first and second well regions.

### BRIEF DESCRIPTION OF DRAWINGS

FIG. 1A is a schematic plan view of a small portion of a conventional power MOSFET.

FIG. 1B is a schematic cross-sectional diagram taken along the line 1B-1B of FIG. 1A with the gate electrodes and various of the upper metallization and dielectric layers of the power MOSFET that are omitted in FIG. 1A added for context.

FIG. 2 is a schematic graph illustrating the reverse recovery characteristics of a body diode in a MOSFET.

FIG. 3 is a graph that illustrates the distribution profile of minority carriers within the body diodes of two different MOSFETs during forward bias operation.

FIG. 4A is a schematic plan view of a top surface of a small portion of the semiconductor layer structure of a power MOSFET according to embodiments of the present invention.

FIG. 4B is a schematic cross-sectional diagram taken along the line 4B-4B of FIG. 4A with the gate electrodes and various of the upper metallization and dielectric layers of the power MOSFET added for context.

FIGS. 5A-5E are schematic cross-sectional diagrams illustrating an example method of fabricating the power MOSFET of FIGS. 4A-4B.

FIG. 6A is a plan view of the upper surface of a small portion of the semiconductor layer structure of a power MOSFET according to further embodiments of the present invention.

FIG. 6B is a schematic cross-sectional diagram taken along the line 6B-6B of FIG. 6A with the gate electrodes and various of the upper metallization and dielectric layers of the power MOSFET added for context.

FIGS. 7A-7D are cross-sectional views illustrating additional modified versions of the power MOSFET of FIGS. 4A-4B.

FIG. 8A is a schematic plan view of a top surface of a small portion of an active region of a semiconductor structure of a power MOSFET according to embodiments of the present invention.

FIG. 8B is a schematic cross-sectional diagram taken along the line 8B-8B of FIG. 8A with the gate electrodes and various of the upper metallization and dielectric layers of the power MOSFET added for context.

FIG. 9 is a schematic plan view of an upper surface of a small portion of an active region of the semiconductor structures of a power MOSFET that is similar to the power MOSFET of FIGS. 8A-8B, but which has a different design for the well implant and source regions.

FIG. 10A is a schematic cross-sectional diagram corresponding to line 8B-8B of FIG. 8A that illustrates a power MOSFET according to another embodiment of the present invention.

FIG. 10B is a greatly enlarged view of one of the well implant regions shown in FIG. 10A.

FIGS. 11-17 are schematic cross-sectional diagrams illustrating power MOSFETS according to additional embodiments of the present invention where each of the cross-sections corresponds to line 8B-8B of FIG. 8A.

FIGS. 18A-18C are schematic horizontal cross-sectional views taken through the semiconductor structures of modified versions of the power MOSFETS of FIGS. 10A-10B, 11 and 14, respectively.

FIG. 19A is a schematic plan view of a top surface of a small portion of an active region of a semiconductor structure of a power MOSFET according to further embodiments of the present invention.

FIG. 19B is a schematic cross-sectional diagram taken along line 19B-19B of FIG. 19A with the gate electrodes and various of the upper metallization and dielectric layers of the power MOSFET added for context.

FIG. 20 is a schematic horizontal cross-sectional view of a small portion of semiconductor structure of a power MOSFET according to still further embodiments of the present invention.

It will be appreciated that the thicknesses of various of the layers and regions in are not necessarily drawn to scale in the drawings.

### DETAILED DESCRIPTION

One parameter that is used to characterize the reverse recovery performance of a body diode is its “snappiness.” Generally speaking, a high degree of snappiness correlates to increased switching times and/or higher switching losses, both of which are undesirable. The body diodes used in many conventional power semiconductor devices may exhibit high degrees of snappiness.

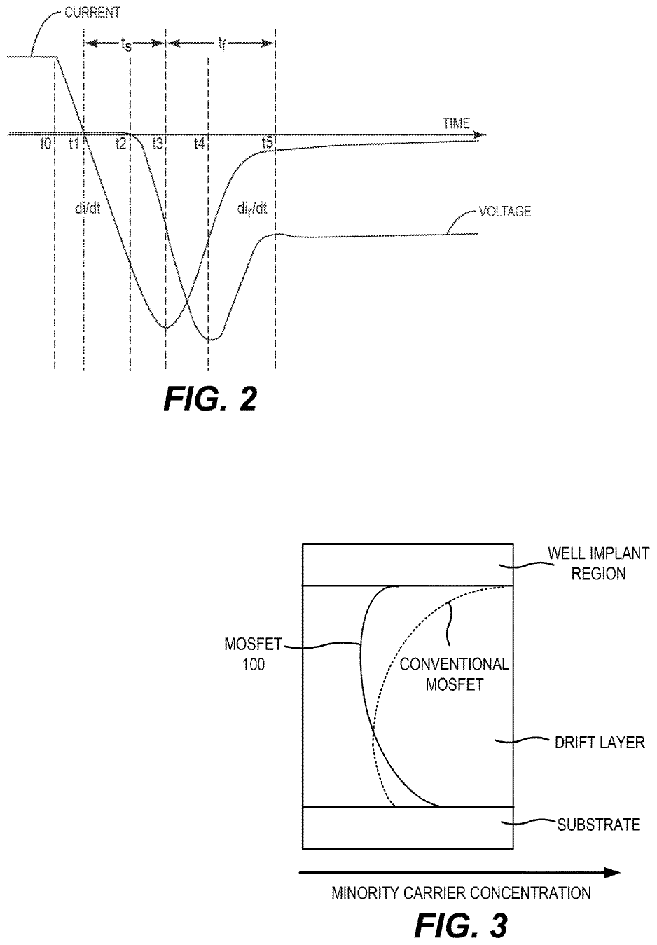

FIG. 2 is a schematic graph that shows the forward current and voltage across a body diode of a MOSFET when the body diode of the MOSFET switches from forward conduction to reverse bias (blocking). Before time t0, the body diode is forward biased and thus conducting current from anode to cathode. The voltage across the body diode is thus around zero. During forward bias operation, excess minority carriers are injected into the drift layer of the MOSFET (and hence into the body diode) such that the drift layer contains excess minority carriers. At time t0, the body diode is switched from forward bias to reverse bias by changing the voltages supplied at the anode and cathode thereof. The current through the body diode thus begins to decrease as excess minority carriers decay. Because of the current flow from the excess minority carriers, the voltage across the body diode remains the same. At time t1, the current through the body diode switches from a positive current to a negative current. The voltage across the body diode continues to remain the same. As the stored excess minority carriers in the drift layer begin to decrease, a resistance of the drift region increases. Accordingly, at time t2 the voltage across the body diode begins to decrease, while the current continues to decrease. The depletion region begins to form at this time. At time t3, the reverse current through the body diode reaches its maximum value when very few excess minority carriers are left in the drift layer. At time t4, the negative voltage across the body diode reaches its peak value. The current through the body diode and the voltage across it continue to increase until time t5 when they stabilize at zero and the reverse voltage, respectively.

The time between when the current through the body diode passes through zero (t1) and reaches its negative peak value (t3) is designated as tₛ in FIG. 2. The time between when the current through the body diode reaches its negative peak value (t3) and when it recovers to 0.2*I_{RRM} (t4) is designated as t_{f} in FIG. 2 (where I_{RRM} refers to the current during reverse recovery). The ratio between t_{f} and tₛ (t_{f}/tₛ) is defined as a softness factor of the body diode. The softness factor is inversely correlated with snappiness of the body diode. Accordingly, a higher softness factor (and hence a lower snappiness) is desirable.

FIG. 3 is a schematic diagram that illustrates the distribution profile of minority carriers within both a conventional MOSFET (dashed line) and a MOSFET according to embodiments of the present invention (solid line) during forward bias operation. The dashed and solid lines in FIG. 3 illustrate the minority carrier concentration (the horizontal axis) as a function of depth (the vertical axis) within the drift layer, with the concentration increasing as the dashed/solid lines extend further to the right. Conventionally, those skilled in the art focus on optimizing the tradeoff between the breakdown voltage and the on-state resistance of a power MOSFET, and typically do not focus on the design of the body diode. As shown by the dashed line in FIG. 3, when this approach is taken, there tends to be a high concentration of minority carriers at the interface between the well implant region and the drift layer. When the concentration of minority carriers is high, it takes longer to sweep the minority carriers out of the upper portion of the drift layer, which delays formation of the depletion region. This prolongs tₛ, thereby increasing the snappiness of the body diode, which degrades the switching performance of the power MOSFET. Moreover, a conventional MOSFET may have a relatively low concentration of minority carriers at the interface between the drift layer and the substrate, as is also illustrated by the dashed line in FIG. 3. As the depletion region grows, these carriers may be swept out of the drift layer thus causing the depletion layer to punch through into the substrate. This will also degrade the performance of the MOSFET due to the sudden disappearance of the diffusion capacitance within the body diode.

As will be discussed in greater detail below, the power MOSFETs according to embodiments of the present invention may have body diodes that have the minority carrier distribution profile, during forward bias operation, that is shown by the solid line in FIG. 3. As shown, the minority carrier concentration in the upper portion of the drift layer is relatively low, which allows the minority carriers to be more quickly swept out of the upper portion of the drift layer when the MOSFET is switched to reverse bias operation, allowing the depletion region to form more quickly. This reduces the time tₛ, which decreases the snappiness of the body diode. The concentration of minority carriers near the interface between the drift layer and the substrate is increased, and is higher than the minority carrier concentration in the upper portion of the drift layer. This prolongs t_{f}, which also acts to decrease the snappiness of the body diode, which is desirable.

Pursuant to embodiments of the present invention, vertical power MOSFETs and other gate-controlled power semiconductor devices are provided that have body diodes that exhibit improved snappiness. As discussed above, the snappiness of a body diode may be reduced by reducing the concentration of minority carriers at the interface between the well implant region and the drift layer. However, since the minority carriers are injected into the drift layer from the well implant region, techniques that increase recombination of minority carriers in the upper portion of the drift layer may also reduce the number of minority carriers that flow to the lower portion of the drift layer. As is also discussed above, the snappiness of a body diode may also be reduced by increasing the concentration of minority carriers at the interface between the drift layer and the substrate. Thus, while reducing the concentration of minority carriers at the interface between the well implant region and the drift layer may beneficially reduce the snappiness of the body diode, it also may reduce the concentration of minority carriers at the interface between the drift layer and the substrate, which may increase the snappiness of the body diode.

As disclosed herein, pursuant to some embodiments of the present invention, power MOSFETs are provided that have first conductivity type drift layers that have a first region that has a first peak doping concentration and a second region that has a second peak doping concentration that is higher than the first peak doping concentration. These MOSFETs also include a plurality of second conductivity type well implant regions, where each well implant region comprises a well region having a third doping concentration and a well contact region having a fourth doping concentration that is higher than the third doping concentration. The first region of the drift layer may be a lower portion of the drift layer and the second region of the drift layer may be an upper portion of the drift layer. The second region of the drift layer may be formed by ion implantation, and may extend underneath the well implant regions. Openings may be provided in the second region of the drift layer. The first region of the drift layer may extend into these openings. While the first and second regions of the drift layer may both comprise n-type silicon carbide regions, the openings in the second region of the drift layer can readily be identified because these regions have the lower doping concentration associated with the first region of the drift layer and may be un-implanted regions, whereas the second region of the drift layer may comprise an implanted region. The openings in the second region of the drift layer may be provided underneath the respective well implant regions. For example, an opening may be formed underneath, and vertically overlapping, the well contact region of each well implant region.

While not intending to be bound by any particular theory of operation, it is believed that the well contact regions may be the primary supplier of the minority carriers that are present in the drift layer. Having the implanted second region of the drift layer extend underneath each well implant region acts to reduce the concentration of minority carriers in the drift layer for two regions. First, the damage to the crystal lattice from the ion implantation process used to form the second region of the drift layer generates recombination centers in the upper portion of the drift layer just below each well implant region. These recombination centers neutralize minority carriers. Second, the higher first conductivity type doping density of the second region of the drift layer (as compared to the first region of the drift layer) provides more majority carriers that can recombine with the minority carriers. Thus, by implanting the upper portion of the drift layer to provide the more highly-doped second region, the minority carrier concentration in the upper portion of the body diode during forward bias operation may be reduced, which helps reduce the snappiness of the body diode.

The openings in the second region of the drift layer, however, have the opposite effect, as these regions have lower n-type dopant concentrations and may not have ion implant damage. As such, minority carriers may more readily be injected into the body diode through these openings, and may persist within the drift region when the MOSFET switches to reverse bias operation. Again, while not intending to be bound by any particular theory of operation, it is believed that the more effective injection of minority carriers into the drift layer that is facilitated by the openings in the second portion of the drift layer may help increase the concentration of minority carriers at the interface between the drift layer and the substrate. While the openings may also increase the concentration of minority carriers at the interfaces between the well implant regions and the drift layer, the openings in the second region of the drift layer may be relatively small, and hence the remainder of the second region of the drift layer can act to reduce the concentration of minority carriers at the interfaces between the well implant regions and the drift layer. Thus, while the openings in the second region of the drift layer may increase the concentration of minority carriers at the interfaces between the well implant regions and the drift layer, it also increases the concentration of minority carriers at the interface between the drift layer and the substrate, and in some cases, this may be a favorable tradeoff that results in an overall reduction in the snappiness of the body diode.

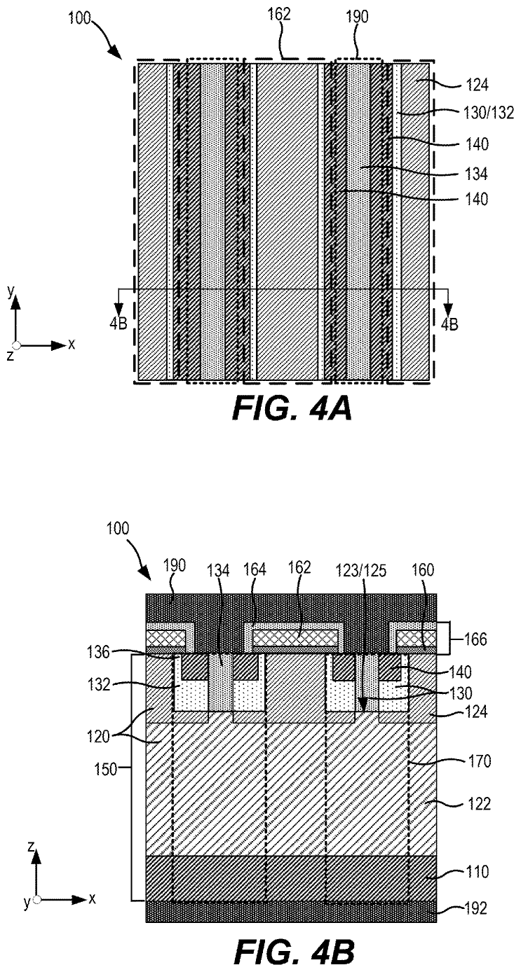

Example embodiments of power semiconductor devices according to embodiments of the present invention will now be described with reference to FIGS. 4A-20. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs) and the like.

FIG. 4A is a schematic plan view of a top surface of a semiconductor layer structure of a planar gate vertical power MOSFET 100 according to embodiments of the present invention. Power MOSFET 100 has a so-called “stripe configuration” in which the well implant regions thereof are formed as continuous stripes that extend in parallel to each other within the semiconductor layer structure. While FIG. 4A illustrates the upper surface of the silicon carbide semiconductor layer structure of power MOSFET 100, the dashed lines show where three gate electrodes are formed above an upper surface of the semiconductor layer structure (with respective gate dielectric layers separating each gate electrode from the semiconductor layer structure), and the dotted lines show where a source metallization of MOSFET 100 contacts the semiconductor layer structure in regions in between adjacent gate electrodes. FIG. 4B is a schematic cross-sectional diagram of the power MOSFET 100 taken along line 4B-4B of FIG. 4A with the gate electrodes and upper metal and dielectric layers of power MOSFET 100 are added for context.

Referring to FIGS. 4A-4B, power MOSFET 100 includes an n-type silicon carbide semiconductor substrate 110 such as, for example, a single crystal 4H silicon carbide semiconductor substrate that is heavily-doped with n-type impurities. The n-type doping concentration of the substrate 110 may be, for example, between 1×10¹⁸ atoms/cm³ and 1×10²¹ atoms/cm³, although other doping concentrations may be used. Herein, the “doping concentration” of a semiconductor material refers to the number of dopant atoms that cause the semiconductor material to have a certain conductivity type (i.e., either n-type or p-type) that are present within a given volume of the semiconductor material (as measured using standard measurement techniques such as Secondary Ion Mass Spectrometry) minus the number of dopant atoms that have the opposite conductivity type that are present in the same region of the semiconductor material. Thus, for an n-type semiconductor material, references to the doping concentration refer to the concentration of n-type dopants minus the concentration of p-type dopants, and for a p-type semiconductor material, references to the doping concentration refer to the concentration of p-type dopants minus the concentration of n-type dopants. The substrate 110 may be any appropriate thickness (e.g., between 10 and 500 microns thick), and it will be appreciated that the substrate 110 will typically be much thicker than shown. The thickness of various other layers of power MOSFET 100 likewise may not be shown to scale in order to allow other portions of the device to be enlarged in the figures. The substrate 110 may be partially or fully removed in some embodiments.

A lightly-doped n-type silicon carbide drift layer 120 is provided on the upper surface of the substrate 110. The n-type silicon carbide drift layer 120 may have a first region 122 and a second region 124 that have different peak doping concentrations. In particular, the first region 122 may comprise the lower portion of the drift layer 120, and the second region 124 may be formed on an upper surface of the first region 122. The second region 124 of the drift layer 120 has a higher peak doping concentration than the first region 122 of the drift layer 120. The first (lower) region 122 of the n-type silicon carbide drift layer 120 may be formed by, for example, epitaxial growth on the silicon carbide substrate 110. The first region 122 of the drift layer 120 may have, for example, an n-type doping concentration of 1×10¹⁴ to 5×10¹⁶ dopants/cm³. The doping concentration may vary with the voltage blocking rating of the device, with devices having higher voltage blocking ratings typically having lower doping concentrations in the drift layer 120. For example, in a MOSFET having a voltage blocking rating of 10 kV, the doping concentration of the first region 122 of the drift layer 120 may be between 1×10¹⁴ to 5×10¹⁴ dopants/cm³, whereas in a MOSFET having a voltage blocking rating of 500-1200 V, the doping concentration of the first region 122 of the drift layer 120 may be between 1×10¹⁶ to 5×10¹⁶ dopants/cm³. The n-type silicon carbide drift layer 120 may have a thickness of, for example, 3-50 microns.

The second region 124 of the n-type silicon carbide drift layer 120 may be formed by, for example, a combination of epitaxial growth and ion implantation, or by ion implantation only, although other formation techniques are possible. When both epitaxial growth and ion implantation are used to form the second region 124 of the drift layer 120, an epitaxial growth process may be used to form a preliminary drift layer on the silicon carbide substrate 110 that has, for example, an n-type doping concentration that matches the doping concentration of the first region 122 of the drift layer 120 in the completed power MOSFET 100. An ion implantation process is then used to implant additional n-type dopants into an upper portion of the preliminary drift layer, thereby converting the upper portion of the preliminary drift layer into the second region 124 of the drift layer 120, thereby forming the drift layer 120 that has a first region 122 with a lower peak doping concentration and a second region 124 with a higher peak doping concentration. The peak doping concentration of the second region 124 of the drift layer 120, may be, for example, between 1.5 to 4.0 times higher than the peak doping concentration of the first region 122 of the drift layer 120. The second region 124 of the drift layer 120 may be a single continuous region or may comprise a plurality of spaced apart second regions 124 depending upon the design of power MOSFET 100.

As shown in FIG. 4B, the second region 124 of the drift layer 120 may be formed in between adjacent well implant regions 130 (discussed below) and may also extend underneath the well implant regions 130. The second region 124 of the drift layer 120 includes a plurality of “cutout” regions or “opening” 125 which are areas where the second region 124 of the drift layer 120 is not formed. The openings 125 may, for example, be formed underneath and vertically overlapping the well contact regions 134 (which are discussed below). The openings 125 may be formed by forming an ion implantation mask that covers certain areas of the preliminary drift layer during the ion implantation process used to form the second region 124 of the drift layer 120. Ions are not implanted into portions of the preliminary drift layer that are covered by the mask, and hence these portions of the preliminary drift layer are not further doped and hence remain part of the first region 122 of the drift layer 120. As such, the first region 122 of the drift layer 120 includes a plurality of upwardly-extending protrusions 123 that fill the respective openings 125 in the second region 124 of the drift layer 120.

A plurality of p-type well implant regions 130 are formed in upper portions of the n-type drift layer 120. As shown best in FIG. 4A, the well regions 130 may extend as stripes in a first direction (the y-direction in FIG. 4A), and may be spaced apart from each other in a second direction (here, the x-direction) that is perpendicular to the first direction. The well implant regions 130 extend to a predetermined depth into the drift layer 120 in a third direction (here, the z-direction) that is perpendicular to both the first direction and the second direction.

Each well implant region 130 may comprise a p-type well region 132 that has a third peak doping concentration and a p-type well contact region 134 that has a fourth peak doping concentration that is greater than the third peak doping concentration. In n-type power MOSFETs such as power MOSFET 100, the well regions 132 are often referred to as “p-wells” 132. Each p-well 132 may have a doping concentration of, for example, between 5×10¹⁵ cm⁻³ and 5×10¹⁹ cm⁻³ and, more typically, between 5×10¹⁶ cm⁻³ and 5×10¹⁹ cm⁻³. The p-wells 132 may be formed via ion implantation. The p-wells 130 typically have a doping concentration that varies with depth, with upper outer portions of each p-well 132 being less heavily doped than lower portions of the p-wells 130. Thus, each p-well 132 may have a graded p-type doping profile with the doping concentration increasing with increasing depth. As will be discussed in further detail below, the upper outer regions of the p-wells 132 act as channel regions 136 during on-state operation, and the doping concentration of the channel regions 136 is typically selected based on various performance characteristics of the power MOSFET, including a desired on-state resistance value. The lower portions of the p-wells 132 are typically more heavily doped p-type than the channel regions 136 to enhance the electric field blocking properties of the well implant regions 130.

The well contact regions 134 are formed within the respective well implant regions 130. Each well contact region 134 may extend to an upper surface of its well implant region 130 and may have a doping concentration of, for example, about 1×10¹⁹/cm³ to 1×10²¹ cm³, such as, for example, about 5×10¹⁹/cm³ to 5×10²⁰ cm³ or about 5×10¹⁹/cm³ to 1×10²⁰ cm³. Each well contact region 134 may directly contact the p-well 132 in which it is formed (which may be referred to herein as its “associated p-well”), and may extend as deep into the drift layer 120 as its associated p-well 132 in some embodiments. It will be appreciated, however, that embodiments of the present invention are not limited thereto. For example, in other embodiments the well contact regions 134 may not extend as deeply into the drift layer 120 as their associated p-wells 132 (in which case the well contact regions 134 may not directly contact the drift layer 120), while in other embodiments the well contact regions 134 may extend deeper into the drift layer 120 than their associated p-wells 132. Since the well contact regions 134 extend to the upper surface of the drift layer 120, they may directly contact the source metallization 190 (discussed below), thereby forming a low resistivity connection between the well implant regions 130 and the source metallization 190.

Heavily-doped n-type silicon carbide source regions 140 are formed in upper portions of the well implant regions 130. The source regions 140 may have a doping concentration of, for example, between 5×10¹⁸ cm⁻³ and 5×10²¹ cm⁻³. The source regions 140 are typically formed via ion implantation. In the depicted embodiment, the well contact regions 134 and the source regions 140 each extend as stripes in the y-direction, and hence two source regions 140 are formed in each well implant region 130. Embodiments of the present invention are not limited thereto. For example, in other embodiments, each well contact region 134 that is shown in FIG. 4A may be replaced with a series of much smaller well contact regions that are spaced apart from each other in the y-direction. In such an embodiment, a single continuous source region 140 is formed within each well implant region 130, and the smaller well contact regions 134 appear as islands within the continuous source region when the semiconductor layer structure of power MOSFET 100 is viewed from above.

The substrate 110, the drift layer 120 (including the first region 122 and the second region 124), the well implant regions 130 (including the p-wells 132 and the well contact regions 134), and the source regions 140 together comprise the semiconductor layer structure 150 of power MOSFET 100. FIG. 4A is a plan (top-down) view of the semiconductor layer structure 150.

As shown in FIG. 4B, a plurality of gate insulating layers 160 are formed on the upper surface of the semiconductor layer structure 150. Each gate insulating layer 160 may comprise, for example, a silicon oxide layer, although other insulating materials may be used. A plurality of gate electrodes 162 are formed on the respective gate insulating layers 160. Each gate electrode 162 may comprise, for example, a conductive material such as polysilicon, a silicide or a metal. A plurality of intermetal dielectric layers 164 may cover the respective gate electrode layers 162. Each intermetal dielectric layer 164 may comprise, for example, a silicon oxide layer. The combination of a gate insulating layer 160, the gate electrode 162 formed thereon, and the intermetal dielectric layer 164 covering the gate electrode may be referred to as a gate structure 166. As can be inferred from FIGS. 4A and 4B, the gate structures 166 extend on top of the semiconductor layer structure 150 as stripes in the y-direction. The upper surface of the semiconductor layer structure 150 (and, more particularly, the well contact regions 134 and the source regions 140) is exposed between each pair of adjacent gate structures 166. A source metallization 190 is formed over the intermetal dielectric layer 164 and on the exposed portions of the semiconductor layer structure 150 so that the source metallization 190 makes physical and electrical contact to the of the n-type source regions 140 and the p-type well contact regions 134 while being electrically insulated from the gate electrode 162. The source metallization 190 may comprise, for example, metals such as nickel, titanium, tungsten and/or aluminum, and/or alloys and/or thin layered stacks of these and/or similar materials. The source metallization 190 may also include a silicide layer that directly contacts the semiconductor layer structure top form an ohmic contact. A drain contact 192 may be formed on the lower surface of the substrate 110. The drain contact 192 may comprise, for example, the same or similar materials to the source metallization layer 190, and may form an ohmic contact to the silicon carbide substrate 110.

As discussed above, power MOSFETs such as power MOSFET 100 include body diodes that are connected in anti-parallel so that the MOSFET can conduct current bidirectionally. In particular, the body diodes allow current to flow from the source to the drain in a reverse conduction mode of operation.

As shown in FIG. 4B, a plurality of body diodes 170 are formed in power MOSFET 100. Each body diode 170 may comprise a PiN diode with the well implant region 130 acting as the p-type region, the substrate 110 acting as the n-type region, and the drift layer 120 acting as the i-type region (which is actually a lightly-doped n-type region).

As discussed above, the “snappiness” of a body diode is a measure of its reverse recovery characteristics. It is desirable to reduce both the switching time and the switching losses of a power MOSFET. Generally speaking, the higher the snappiness of the body diodes, the longer the switching times and the higher the switching losses. Thus, it is desirable to reduce the snappiness of the body diodes in a power MOSFET.

The body diodes 170 in power MOSFET 100 may exhibit reduced snappiness as compared to the body diodes in conventional power MOSFETs. As discussed above with reference to FIG. 3, the snappiness of a body diode may be reduced by reducing the concentration of minority carriers at the interface between the well implant region and the drift layer and/or by increasing the concentration of minority carriers at the interface between the drift layer and the substrate (at least to an extent that prevents depletion region punch-through into the substrate). However, since the minority carriers are injected into the drift layer from the well implant region, techniques that increase recombination of minority carriers in the upper portion of the drift layer may also reduce the number of minority carriers that flow to the lower portion of the drift layer. In other words, a tradeoff may exist with respect to the number of minority carriers that are injected into the drift layer.

The body diodes 170 of power MOSFET 100 may provide improved snappiness performance because, for example, they have the second region 124 of the drift layer 120 extend underneath the well implant regions 130 and because openings 125 are provided at selected locations within the second region 124 of the drift layer 120. As discussed above, the second region 124 of the drift layer 120 may be formed by ion implantation, which results in damage to the silicon carbide lattice in the portion of the drift layer 120 that is immediately below each well implant region 130. The ion implantation damage forms recombination centers that reduce the minority carrier concentration through recombination. In addition, the second region 124 of the drift layer 120 has an increased n-type doping concentration as compared to the remainder of the drift layer 120. This higher doping concentration acts to provide additional majority carriers that can recombine with the minority carriers. Thus, by implanting the upper portion of the drift layer 120 to provide the more highly-doped second region 124, the minority carrier concentration in the upper portion of the body diode 170 during forward bias operation may be reduced, which helps reduce the snappiness of the body diode 170.

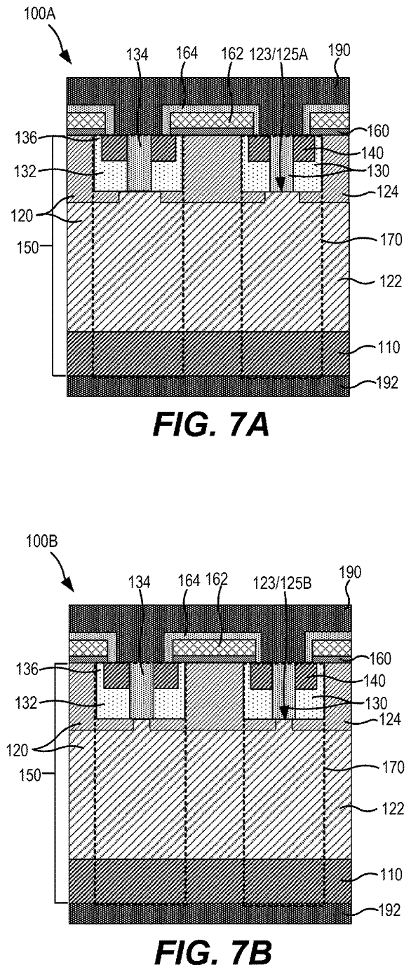

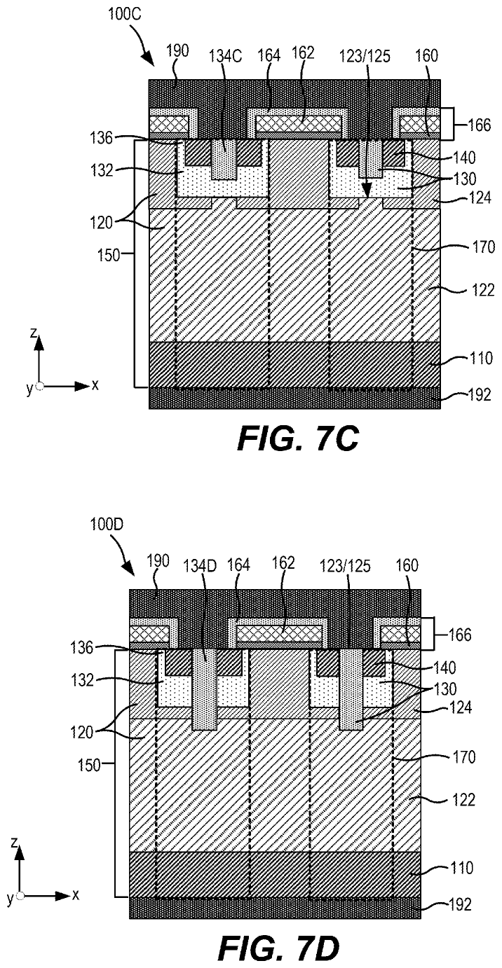

In FIG. 4B, the openings 125 are shown as having the same width in the x-direction as the well contact regions 134. It will be appreciated that embodiments of the present invention are not limited thereto. For example, as discussed below with reference to FIGS. 7A and 7B, in other embodiments, the openings 125 may have widths in the x-direction that are wider or narrower than the width of each well contact region 134. More generally, an area in the plane defined by the x-direction and the y-direction of each opening 125 may be greater than, equal to, or less than an area in the same plane of the bottom surface of the well contact region 134 that overlies each opening 125.

The second region 124 of the drift layer 120 also includes the plurality of openings 125, and the first region 122 of the drift layer 120 may extend into these openings 125. Moreover, in some embodiments, each well contact region 134 may extend through its associated p-well 132 to directly contact the first region 122 of the drift layer 120. This configuration allows minority carriers to more easily populate within the drift layer 120, which may beneficially increase the concentration of minority carriers at the interface between the drift layer 120 and the substrate 110, so that punch-through is avoided. While the openings 125 may also increase the concentration of minority carriers at the interfaces between the well implant regions 130 and the drift layer 120, the openings 125 in the second region 124 of the drift layer 120 may be relatively small, and hence the remainder of the second region 124 of the drift layer 120 can act to reduce the concentration of minority carriers at the interfaces between the well implant regions 130 and the drift layer 120. As a result, in overall improvement in performance may be obtained.

U.S. Pat. No. 11,769,827 (“the '827 patent”) discusses various techniques for reducing the snappiness of the body diodes in a silicon carbide based power MOSFET by reducing the concentration of minority carriers at the interfaces between the well implant regions and the drift layer. In particular, the '827 patent discusses (1) reducing the doping concentration of the well implant regions and (2) intentionally damaging an upper portion of the drift layer by implanting non-dopant elements such as argon, hydrogen and/or helium into the drift region in order to form recombination regions in the drift layer. The '827 patent explains that both of these techniques can reduce the minority carrier concentration in the upper portion of the drift layer. Notably, the approaches for improving the snappiness of the body diodes 170 that are disclosed herein are different than the approaches suggested in the '827 patent, as the power semiconductor devices according to embodiments of the present invention may have heavily-doped well contact regions 134 that extend to the bottom of the well implant regions 130 and because inactive dopants need not be (but can) be injected into the drift layer.

Referring again to FIGS. 4A-4B, pursuant to some embodiments of the present invention, semiconductor devices such as power MOSFET 100 are provided that comprises a semiconductor layer structure 150 that comprises a drift layer 120 having a first conductivity type (here n-type) and a plurality of well regions 132 having a second conductivity type (here, p-type) in the drift layer 120. The drift layer 120 comprises a first region 122 that has a first peak doping concentration and a second region 124 that has a second peak doping concentration type that is greater than the first peak doping concentration. The second region 124 of the drift layer 120 comprises an implanted region and extends between adjacent well regions 132 and underneath the well regions 132. The well regions 132 extend to an upper surface of the semiconductor layer structure 150. The second region 124 of the drift layer 120 comprises a plurality of openings 125, and the first region 122 of the drift layer 120 is exposed through the openings 125 in the second region 124 of the drift layer 120.

In some embodiments, the second region 124 of the drift layer 120 is on top of the first region 122 of the drift layer 120. The first region 122 of the drift layer 120 may extend into the openings 125 in the second region 124 of the drift layer 120.

In some embodiments, the semiconductor layer structure 150 may further comprise a plurality of well contact regions 134 that have the second conductivity type that are in the respective well regions 132, each well region 132 and the well contact region 134 within the well region 132 together forming a respective well implant region 130, where the well contact regions 134 have a higher peak doping concentration than the well regions 132. Each well contact region 134 may be above and vertically overlapping a respective one of the openings 125 in the second region 124 of the drift layer 120. A first of the well contact regions 134 is within the first of the well regions 132 and vertically overlaps a first of the openings 125 in the second region 124 of the drift layer 120. In some embodiments, a first area of a bottom of the first of the openings 125 is greater than a second area of a bottom surface of the first of the well contact regions 134. In other embodiments, the first area of the bottom of the first of the openings 125 may be less than or equal to the second area of the bottom surface of the first of the well contact regions 134. Herein a first region in a semiconductor layer structure vertically overlaps a second region in a semiconductor layer structure if an axis exists that is perpendicular to the major surfaces of the semiconductor layer structure that extends through both the first and second regions.

In some embodiments, the first of the well regions 132 extends deeper into the semiconductor layer structure 150 than the first of the well contact regions 134. In some embodiments, the first of the well contact regions 134 directly contacts the first region 122 of the drift layer 120. A bottom surface of the first of the well regions 132 may directly contact the second region 124 of the drift layer 120. In some embodiments, a portion of the drift layer 120 that directly contacts a lower surface of a first of the well implant regions 130 comprises a first portion 124 that is implanted with n-type dopants and a second portion 122 that is not implanted with n-type dopants.

The semiconductor device may further comprise a gate oxide layer 160 on an upper surface of the semiconductor layer structure 150 and a gate electrode 162 on the gate oxide layer 160 opposite the semiconductor layer structure 150, where a bottom surface of the gate electrode 162 is above an uppermost surface of the semiconductor layer structure 150.

The first region 122 of the drift layer 120 may comprise a plurality of upwardly-extending protrusions 123 that are positioned underneath the respective well implant regions 130. The second region 124 of the drift layer 120 may directly contact a bottom surface of the well region 132 and the first region 122 of the drift layer 120 may directly contact a bottom surface of the well contact region 134. The of upwardly-extending protrusions 123 of the first region 122 of the drift layer 120 thus may extend into the respective openings 125 in the second region 124 of the drift layer 120.

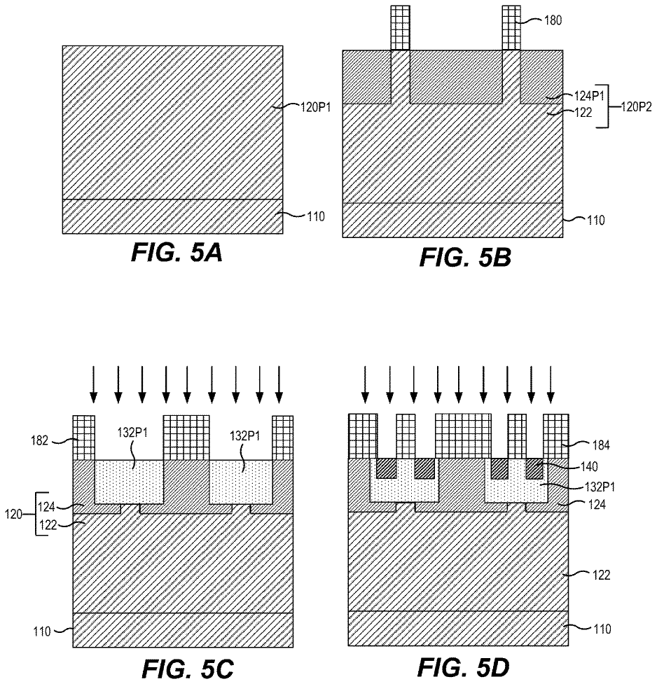

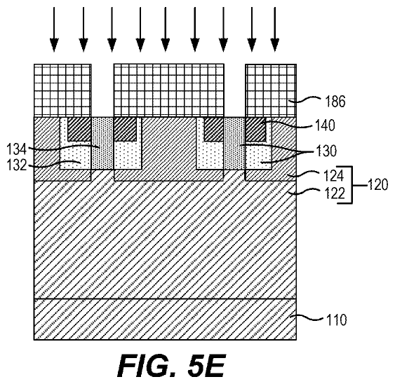

FIGS. 5A-5E are schematic cross-sectional diagrams illustrating a method of fabricating the power MOSFET 100 of FIGS. 4A-4B. The cross-sections of FIGS. 5A-5E are taken along line 4B-4B of FIG. 4A.

Referring to FIG. 5A, a first preliminary drift layer 120P1 is epitaxially grown on the heavily-doped n-type silicon carbide substrate 110. The first preliminary drift layer 120P1 may be an n-type silicon carbide epitaxial layer and may be doped n-type during the epitaxial growth process.

Referring to FIG. 5B, a first ion implantation mask (e.g., a silicon oxide mask) is formed on the upper surface of the first preliminary drift layer 120P1 and then patterned to form a first patterned mask 180 that exposes regions where the openings 125 in the second region of the drift layer 120 are to be formed. Next, an ion implantation process is performed to implant n-type dopants into the upper surface of the first preliminary drift layer 120P1. This ion implantation process converts the first preliminary drift layer 120P1 into a second preliminary drift layer 120P2 that includes a first region 122 that has a first doping concentration and a preliminary second region 124P1 that has a second higher doping concentration.

Referring to FIG. 5C, a second ion implantation mask (e.g., a silicon oxide mask) is formed on the upper surface of the second preliminary drift layer 120P2 and then patterned to form a second patterned mask 182 that exposes portions of the semiconductor layer structure 150 where the well implant regions 130 are to be formed. Next, an ion implantation process is performed to implant p-type dopants into the portions of the upper surface of the second preliminary drift layer 120P2 that are exposed by the second patterned mask 182 to form preliminary p-wells 132P1. The preliminary p-wells 132P1 are not formed as deep into the semiconductor layer structure 150 as the first region 122 of the second preliminary drift layer 120P2. Formation of the preliminary p-wells 132P1 converts the second preliminary drift layer 120P2 into the drift layer 120 having the first region 122 and the second region 124.

Referring to FIG. 5D, a third ion implantation mask (e.g., a silicon oxide mask) is formed on the upper surface of the second preliminary drift layer 120P2 and then patterned to form a third patterned mask 184 that exposes portions of the preliminary p-wells 132P1 where the source regions 140 are to be formed. Next, an ion implantation process is performed to implant n-type dopants into the portions of the upper surface of the preliminary p-wells 132P1 that are exposed by the third patterned mask 184 to form the source regions 140.

Referring to FIG. 5E, a fourth ion implantation mask (e.g., a silicon oxide mask) is formed on the upper surface of the semiconductor layer structure 150 and then patterned to form a fourth patterned mask 186 that exposes portions of the preliminary p-wells 132P1 where the well contact regions 134 are to be formed. Next, an ion implantation process is performed to implant p-type dopants into the portions of the upper surface of the preliminary p-wells 132P1 that are exposed by the fourth patterned mask 184 to form the well contact regions 134 and to convert the preliminary p-wells 132P1 into the p-wells 132 so that well implant regions 130 are formed that each comprise a p-well 132 and a well contact region 134.

In the above description, MOSFETs having a stripe configuration have been described where the well implant regions extend as stripes in the semiconductor layer structure. Additionally, in the above description, the gate electrodes of the MOSFETs extend as stripes on an upper surface of the semiconductor layer structure. It will be appreciated, however, that embodiments of the present invention are not limited to these configurations. For example, power MOSFET 100 could be modified to include a so-called “mesh” gate electrode where gate electrodes are provided that extend in both the y-direction and in the x-direction so that the gate signal can be distributed from one gate electrode to another gate electrode. In addition, the same techniques described above with respect to power MOSFET 100 may be implemented in power MOSFETs that have a so-called cell configuration. Power MOSFETs that have a cell configuration have well regions that are formed as spaced-apart islands within the semiconductor layer structure.

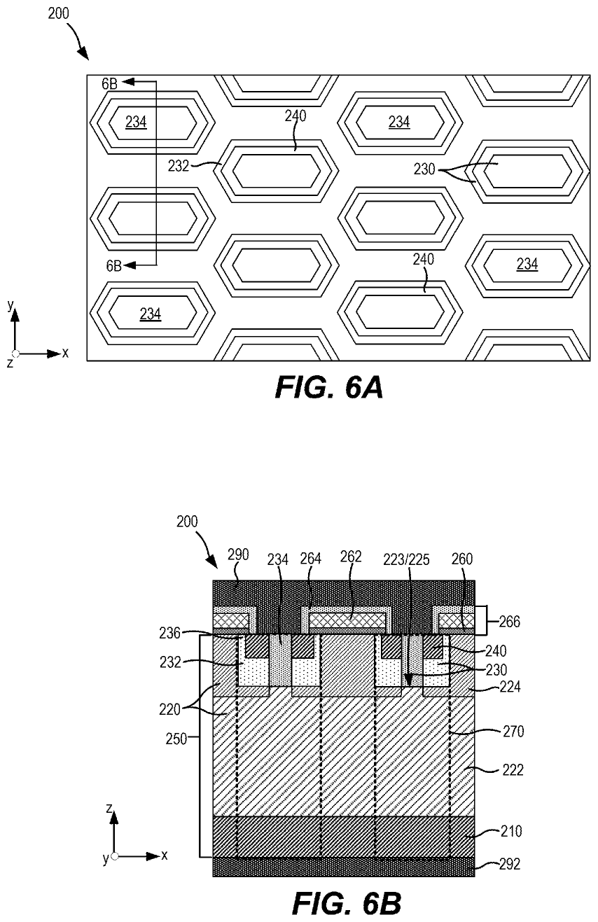

For example, FIGS. 6A-6B illustrate a power MOSFET 200 according to further embodiments of the present invention that has a cell configuration. FIG. 6A is a plan (top) view of the semiconductor layer structure 250 of power MOSFET 200 (i.e., the gate electrodes, upper dielectric layers and metallization layers are removed in the view of FIG. 6A), while FIG. 6B is a schematic cross-sectional view taken along line 6B-6B of FIG. 6A. In FIG. 6A, the dashed lines illustrate where the gate electrode is formed above the semiconductor layer structure 250, and the dotted lines illustrate the locations where a source metallization 290 of power MOSFET 200 directly contact the semiconductor layer structure 250. As shown by the dashed lines in FIG. 6A, a continuous gate electrode 262 extends above the semiconductor layer structure 250 and is separated from the semiconductor layer structure 250 by a continuous gate oxide layer (see FIG. 6B).

Referring to FIGS. 6A-6B, well implant regions 230 are formed in the upper surface of the semiconductor layer structure 250. Each well implant region 230 comprises a p-well 232 and a well contact region 234 that is formed in a central portion of the p-well 232. The well implant regions 230 each have an irregular hexagon shape when viewed from above. Each well implant region 230 comprises a p-well 232 that has an irregular hexagonal ring shape when viewed from above and a p-type well contact region 234 that is formed within the p-well 232. The well contact region 234 has a hexagonal shape when viewed from above. A source region 240 having an irregular hexagonal ring shape when viewed from above is formed in the upper portion of each well implant region between the outer portion of the p-well 232 and the well contact region 234.

As noted above, FIG. 6B is a cross-sectional view taken along line 6B-6B in FIG. 6A. As can be seen, the cross-section of FIG. 6B is identical to the cross-section of FIG. 4B except that all of the reference numerals are increased by 100. Thus, the description of FIG. 4B above applies equally to FIG. 6B, and hence FIG. 6B will not be described further here.

While power MOSFET 200 has hexagonally-shaped cells (e.g., hexagonally-shaped well implant regions), it will be appreciated that embodiments of the present invention are not limited thereto, and that the principles of the present disclosure apply equally to MOSFETs having cell configurations with well implant regions having other shapes including, for example, MOSFETs having triangular, rectangular (e.g., square), and octagonal shaped well implant regions.

FIGS. 7A-7D are cross-sectional views illustrating additional modified versions of the power MOSFET of FIGS. 4A-4B.

As shown in FIG. 7A, a power MOSFET 100A may be identical to power MOSFET 100 except that in power MOSFET 100A the openings 125A in the second region 124 of the drift layer 120 are larger than the openings 125 in power MOSFET 100. As such, each opening 125A exposes not only the bottom surface of its associated well contact region 134, but also exposes part of the bottom surface of its associated p-well 132 so that the first region 122 of the drift layer 120 directly contacts both the bottom surface of the well contact region 134 and the bottom surface of the p-well 132. Power MOSFET 100A may allow greater injection of minority carriers into the drift layer 120 during on-state operation.

As shown in FIG. 7B, a power MOSFET 100B may be identical to power MOSFET 100 except that in power MOSFET 100B the openings 125B in the second region 124 of the drift layer 120 are smaller than the openings 125 in power MOSFET 100. As such, each opening 125B does not expose the entirety of the bottom surface of its associated well contact region 134, and hence the second region 124 of the drift layer 120 may also be in direct contact with the bottom surface of the well contact region 134. Power MOSFET 100B may allow less injection of minority carriers into the drift layer 120 during on-state operation as compared to power MOSFET 100.

As shown in FIG. 7C, a power MOSFET 100C may be identical to power MOSFET 100 except that in power MOSFET 100C the well contact regions 134C do not extend as deeply into the semiconductor layer structure 150 as do the p-wells 132. This acts to reduce the concentration of minority carriers in the drift layer 120 during on-state operation as compared to power MOSFET 100.

As shown in FIG. 7D, a power MOSFET 100D may be identical to power MOSFET 100 except that in power MOSFET 100D the well contact regions 134D extend deeper into the semiconductor layer structure 150 than do the p-wells 132. As such, the well contact regions 134D may extend through the opening 125D in the second region 124 of the drift layer 120. The well contact regions 134D may extend all of the way through the respective openings 125D, as shown, or may only extend part of the way through the respective openings 125D. Having the well contact regions 134D extend deeper into the semiconductor layer structure 150 than the p-wells 132 acts to increase the injection of minority carriers into the drift layer 120 during on-state operation as compared to power MOSFET 100.

It will be appreciated that power MOSFETS 100C and 100D may be modified to have the larger openings 125A shown in FIG. 7A or the smaller openings 125B shown in FIG. 7B in other embodiments.

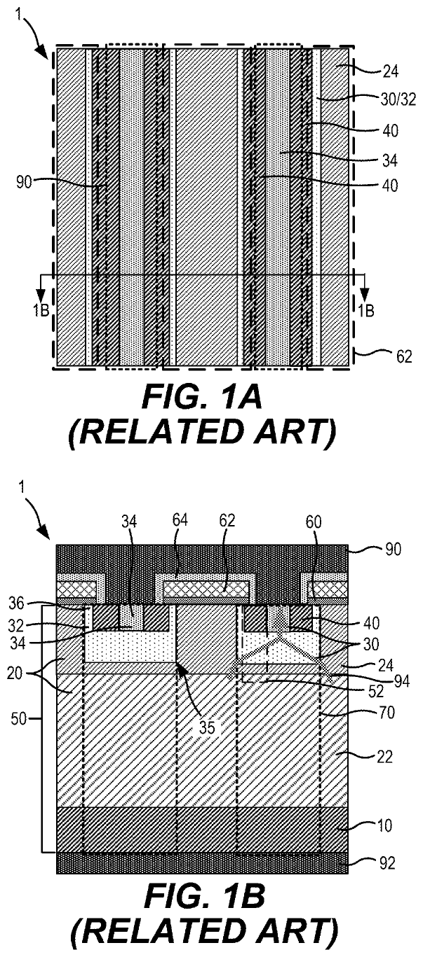

As discussed above with reference to FIG. 1B, semiconductor devices are formed in the semiconductor structure 50 of planar gate vertical MOSFET 1 such as the body diodes 70 that are formed at the interface between each p-well 32 and the drift layer 20 that allow the MOSFET 1 to conduct current bidirectionally. In addition, each source region 40 in conjunction with its associated p-well 32 and the drift layer 20 forms a “parasitic” n-p-n BJT 52 in the semiconductor structure 50. One of the parasitic BJTS is shown in FIG. 1B in the dashed box labelled 52. The parasitic BJT 52 is not controlled by the gate terminal, and hence once turned on it is an uncontrollable current path. While a power MOSFET includes a large number of parasitic BJTS 52 (as each unit cell has a pair of parasitic BJTS 52), the discussion herein will focus on a single one of the parasitic BJTS in each power semiconductor device for ease of description. It will be appreciated that all of the parasitic BJTS will operate in the same manner.

When a high-speed switching circuit such as power MOSFET 1 is coupled to an inductive load, over-voltage transients within the inductive load can generate substantial voltage spikes that are applied to the drain terminal 92 of power MOSFET 1. If these voltage spikes are high enough, a phenomena known as avalanche breakdown can occur where a drain-to-source “avalanche” current is forced through the MOSFET 1 even if it is in its off-state (i.e., even if the voltage applied at the gate terminal is below the threshold voltage). A voltage drop occurs as the avalanche current passes through power MOSFET 1 due to the resistance of the silicon carbide semiconductor structure 50. The magnitude of the voltage drop is a function of the resistance along the avalanche current path.

The avalanche currents typically flow through the p-wells 32 and the p-type well contact regions 34. Since p-type silicon carbide is much more resistive than many semiconductor materials, the resistance of the moderately-doped p-wells 32 may be relatively high, and this increases the voltage drop that occurs as the avalanche current traverses each p-well 32. If the avalanche currents are large enough, the resulting voltage drop can cause the parasitic BJT 52 to turn on. When this occurs, a low resistance drain-to-source current path is formed that carries large currents due to the large differential between the voltages applied at the source and drain terminals. This may result in a “thermal runaway” event where the amount of current flowing through power MOSFET 1 keeps increasing. The large currents passing through the resistive silicon carbide semiconductor structure 50 heat power MOSFET 1 to very high temperatures, eventually destroying MOSFET 1. While parasitic BJTS are present in all vertical power MOSFETS, thermal runaway events are less of a problem in silicon-based power MOSFETS because the resistance of silicon is much less than the resistance of silicon carbide (and particularly of p-type silicon carbide). The much higher resistance levels in silicon carbide power MOSFETS increase the magnitude of the voltage drop that occurs for a given amount avalanche current, which reduces the amount of avalanche current that is sufficient to turn on the parasitic BJT 52.

The magnitude of the voltage drop that occurs as the avalanche current traverses the semiconductor structure 50 is a function of the resistance of the silicon carbide regions along the avalanche current path, the magnitude of the avalanche current, and the distances that the current travels through the silicon carbide regions having different resistance levels. Avalanche breakdown typically occurs at locations within the semiconductor structure 50 which experience the highest electric fields during reverse blocking operation. The highest electric fields may occur adjacent p-n junctions within the device, such as the junctions between the lightly-doped n-type drift region 20 and the p-type well implant regions 30. The high electric fields adjacent these junctions ionize electron-hole pairs. Since electric field crowding effects increase the electric field levels even further at corner regions of the p-n junctions, avalanche breakdown tends to occur at a corner of a p-type region that abuts an n-type region, such as the lower corners of the well regions 32. In these locations, the high electric fields ionize electron-hole pairs, and the holes then flow toward the source metallization 90 while the electrons flow to the drain terminal 92. Referring again to FIG. 1B, the large bold arrows illustrate the flow of holes (i.e., the avalanche current) that result when conventional power MOSFET 1 enters avalanche breakdown. As shown, the electron-hole pairs ionize at the sharp lower corners of the p-wells 32 and the holes then travel generally laterally through the lower portions of the p-wells 32 until the holes are underneath the well contact regions 34, at which point the holes flow generally vertically through the well contact regions 34.

As discussed above, thermal runaway events may occur because avalanche currents flowing through the semiconductor structure 50 cause a voltage drop between each p-well 32 and the source regions 40 that are provided in the p-wells 32 that is sufficient to turn on the parasitic BJT 52. These voltage drops occur as the avalanche current flows through each p-well 32, with the amount of voltage drop increasing with increasing current flow. There are two types of avalanche voltage drops. The first type is the voltage drop that occurs in response to small leakage currents that flow through the p-wells 32 during normal reverse blocking operation. The second type of avalanche voltage drop is the voltage drop that occurs in response to the avalanche currents that flow in the semiconductor structure during an unclamped inductive switching event. Embodiments of the present invention are based, in part, on the realization that if the avalanche current can mostly be directed away from the high resistance p-wells 32 and/or if the avalanche current path through the p-wells 32 can be shortened, then the robustness of a power semiconductor device can be improved, since the magnitude of the voltage drop that occurs during an unclamped inductive switching event can be reduced.

Thus, pursuant to further embodiments of the present invention, power semiconductor devices such as vertical planar gate power MOSFETS and devices that include such power MOSFETS (e.g., power IGBTS) are provided that may exhibit improved ruggedness in that they are less susceptible to avalanche breakdown currents initiating a thermal runaway event that destroys the device. The power semiconductor devices according to embodiments of the present invention may take one or more of several different approaches for providing improved ruggedness.

In a first approach, the power semiconductor devices may be configured to direct the avalanche currents away from the high resistance p-wells so that the avalanche current traverses a lower resistance path. This can be accomplished by configuring the device so that, during reverse blocking operation, the electric fields will be increased in regions where induced avalanche currents will flow more directly into the lower resistance well contact region and/or so that the electric fields will be reduced in regions that would direct the avalanche currents through the higher resistance p-well. The more that the avalanche current is redirected away from the p-wells, the smaller the voltage drop that is caused by the avalanche current. This strategic diversion of the avalanche current may prevent the voltage drop from reaching levels that would activate the parasitic BJTS, thereby mitigating the risk of a thermal runaway event.

In a second approach, the voltage drop that occurs along the avalanche current path can be reduced by reducing the distance that the avalanche current travels before reaching a lower resistance region in the device such as the heavily doped well contact region and/or the source metallization.

Each of these approaches enhance the devices ability to withstand higher avalanche currents during, for example, unclamped inductive switching events. Moreover, these approaches can be combined to further improve the ruggedness of the power semiconductor devices according to embodiments of the present invention.

Avalanche energy serves as a quantitative measure of a power semiconductor device's ability to endure an event that generates avalanche currents such as unclamped inductive switching events. Conventionally, a power semiconductor device's ability to endure such an event was limited by inherent physical properties of the device. Thus, if a conventional power semiconductor device did not inherently provide sufficient protection against thermal runaway events, then additional circuitry such as clamping components would be provided to ensure adequate protection. With the techniques disclosed herein, the avalanche energy that a power semiconductor device can withstand may be significantly enhanced, allowing power switching devices to manage higher energy voltage transients without failure and without the need for additional clamping components.

In some embodiments, power semiconductor devices are provided that have heavily doped well contact regions that directly connect to the drift region of the device. The junction between the more heavily-doped well contact regions and the drift region increases the electric field values during reverse blocking operation, and allows the avalanche current to directly enter the lower resistance well contact region without traversing the higher resistance p-well. Moreover, the portions of the heavily doped well contact regions that directly contact the drift region may have sharp corners. The sharp corners may further increase the electric field concentrations in the vicinity of these corners during reverse blocking operation so that the electric fields are highest in these corner regions. As such, when a voltage spike is generated in response to a transient in an inductive load, electron-hole pairs may first start ionizing in the vicinity of the junction between the corner of the heavily doped well contact region and the underlying drift region. Since the well contact regions are located in between the source regions, and since the well contact regions provide the lowest resistance path to the source metallization, the avalanche currents generated by ionization of the electron-hole pairs will primarily flow directly upwardly through the well contact region to the source metallization, with little current flowing into the p-wells. As a result, the likelihood that an avalanche current causes the parasitic BJT to be turned on is reduced, and hence the device may withstand higher avalanche current levels without experiencing a thermal runaway event.

In other embodiments, power semiconductor devices are provided that include well implant regions that, in lateral cross-section, have well regions that have first and second lower corners that face an adjacent JFET region. A gate electrode that vertically overlaps the JFET region may also vertically overlap the first lower corner of the well region, and the first lower corner may be closer to the gate electrode than the second lower corner, which may be deeper within the semiconductor structure and/or spaced farther apart laterally from a JFET region that is underneath the gate electrode than is the first lower corner. Herein, two elements of a semiconductor device “vertically overlap” if an axis that extends perpendicular to the major surfaces of the semiconductor structure of the semiconductor device pass through both elements. The second lower corner may be a sharper corner than the first lower corner. For example, the second lower corner may be a rounded corner that has a smaller radius of curvature than does the first lower corner or may be a sharp corner. As a result, avalanche currents will tend to be generated in the vicinity of the second lower corner, and may therefore be directed away from the portion of the well region that acts as the base of the parasitic BJT. As explained above, this allows the device to handle higher avalanche current levels without triggering a thermal runaway event.

According to still further embodiments of the present invention, power semiconductor devices are provided that include second conductivity type well implant regions on a first conductivity type drift region. Each well implant region comprises at least one second conductivity type well region and a second conductivity type well contact region that has a higher doping concentration than the at least one well region. First and second first conductivity type source regions are formed within the well implant region. In addition, a selectively implanted first conductivity type electric field concentration region is formed underneath the well contact region within a recess in a lower surface of the well implant region. The electric field concentration region may have a higher doping concentration than the drift region and may act to increase electric field levels during an avalanche current event within the recess in the lower surface of the well implant region. These higher electric field levels may direct the avalanche currents to flow through the middle of each well implant region and away from the portions of the well implant region that act as the bases of the parasitic BJTS.

According to still further embodiments of the present invention, power semiconductor devices are provided that include second conductivity type well implant regions that are formed on a first conductivity type drift region. Each second conductivity type well implant region may include a well region and a more highly doped well contact region. The well contact regions extend deeper into the semiconductor structure than does the well region so that the well contact regions directly contact the drift region. During reverse blocking operation, the electric field levels may be enhanced at the junction between the more highly doped well contact regions and the drift region, and hence avalanche currents will tend to form at these locations. The well contact regions are formed in central portions of the respective well implant regions, and hence the avalanche currents tend to flow through the middle of each well implant region and away from the portions of the well implant regions that act as the bases of the parasitic BJTS.

Referring again to FIG. 1B, the bold arrows labelled 94 illustrate the avalanche current paths through the conventional power MOSFET 1. During reverse blocking operation, the electric field levels at the p-n junctions in the semiconductor structure 50 reach their highest levels at the lower corners of the p-wells 32, as the p-n junction enhances the electric fields, and the sharp corners of the p-well 32 cause electric field crowding effects that further increase the electric field levels. When a voltage transient in an inductive load causes voltage spikes that increase the electric fields to levels that are sufficient to ionize a significant number of electron-hole pairs, such ionization will mostly occur at the locations where the electric fields are the highest, namely at the lower corners of the p-wells 32. The freed holes will then primarily travel across the lower portion of the p-well 32 to the well contact region 34, and then through the well contact region 34 to the source metallization 90. As is readily apparent, most of the avalanche current flows through the base of the parasitic BJT 52, and the avalanche current may flow through this high resistance base region for an extended distance. The fact that high current levels are flowing through the base of the parasitic BJT 52 for large distances means that the voltage drop will be large, increasing the likelihood that the parasitic BJT 52 turns on in response to a voltage transient in the inductive load.

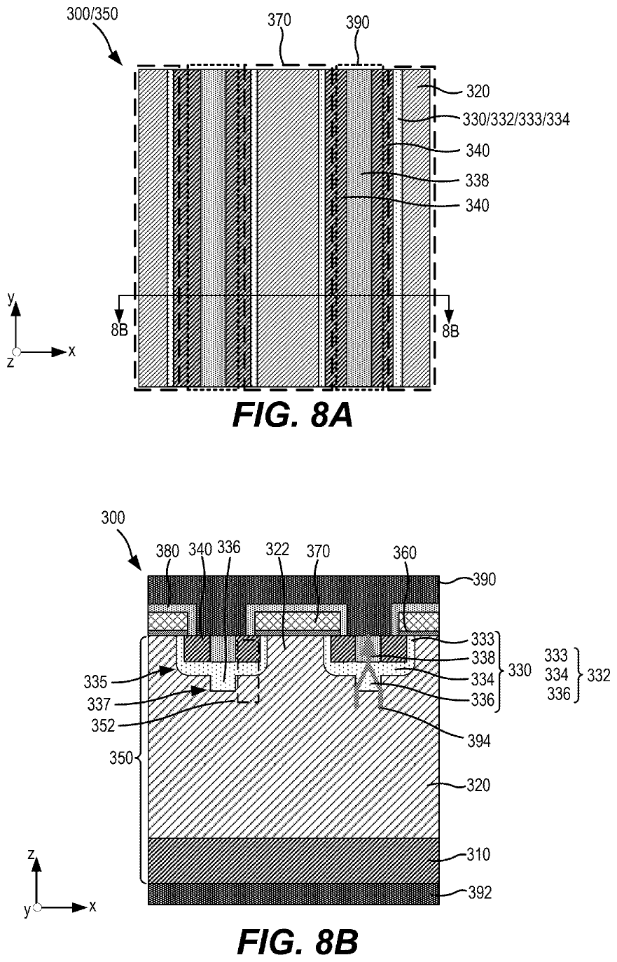

FIG. 8A is a schematic plan view of an upper surface of a semiconductor structure of a planar gate vertical power MOSFET 300 according to embodiments of the present invention. Power MOSFET 300 has a so-called “stripe configuration” in which the well implant regions (i.e., the implanted regions that comprise the p-wells and the well contact regions) thereof are formed as continuous stripes that extend in parallel to each other within the semiconductor structure. While FIG. 8A illustrates the upper surface of the silicon carbide semiconductor structure of power MOSFET 300, the dashed lines show where a first gate electrode and portions of two additional gate electrodes are formed above the upper surface of the semiconductor structure (with respective gate dielectric layers separating each gate electrode from the semiconductor structure), and the dotted lines show where a source metallization of MOSFET 300 contacts the semiconductor structure in regions in between adjacent gate electrodes. FIG. 8B is a schematic cross-sectional diagram of the power MOSFET 300 taken along line 8B-8B of FIG. 8A with the gate electrodes and upper metal and dielectric layers of power MOSFET 300 added for context.

Referring to FIGS. 8A-8B, power MOSFET 300 includes an n-type silicon carbide semiconductor substrate 310 such as, for example, a single crystal 4H silicon carbide semiconductor substrate that is heavily-doped with n-type impurities. The n-type doping concentration of the substrate 310 may be, for example, between 1×10¹⁸ atoms/cm³ and 1×10²¹ atoms/cm³, although other doping concentrations may be used. The substrate 310 may be any appropriate thickness (e.g., between 10 and 500 microns thick), and it will be appreciated that the substrate 310 will typically be much thicker than shown. The thickness of various other layers of power MOSFET 300 likewise may not be shown to scale in order to allow other portions of the device to be enlarged in the figures. The substrate 310 may be partially or fully removed in some embodiments.

A heavily doped n-type buffer layer (not shown) is typically formed by epitaxial growth on the upper surface of the substrate 310. The buffer layer is typically present in silicon carbide based power MOSFETS and is not shown in any of the figures herein as it is not relevant to the inventive subject matter discussed herein. The buffer layer is provided, among other reasons, to improve the quality of the epitaxial grown layers of the semiconductor structure.

A lightly-doped n-type silicon carbide drift region 320 is provided on the upper surface of the substrate 310, with the buffer layer disposed between the substrate 310 and the drift region 320. In the depicted embodiment, the n-type silicon carbide drift region 320 has a relatively constant doping density throughout, although it will be appreciated that embodiments of the present invention are not limited thereto. For example, an upper portion of the drift region 320 may have a higher doping concentration than the remainder of the drift region 320 in order to reduce the on-state resistance of the device and/or to better distribute the on-state currents throughout the drift region 320. The drift region 320 may be formed by, for example, epitaxial growth on the silicon carbide substrate 310. The drift region 320 may have, for example, an n-type doping concentration of 1×10¹⁴ to 5×10¹⁶ dopants/cm³. The doping concentration may vary with the voltage blocking rating of the device, with devices having higher voltage blocking ratings typically having lower doping concentrations in the drift region 320. For example, in a MOSFET having a voltage blocking rating of 10 kV, the doping concentration of the drift region 320 may be between 1×10¹⁴ to 5×10¹⁴ dopants/cm³, whereas in a MOSFET having a voltage blocking rating of 500-1200 V, the doping concentration of the drift region 320 may be between 1×10¹⁶ to 5×10¹⁶ dopants/cm³. The n-type silicon carbide drift region 320 may have a thickness of, for example, 3-50 microns, with thicknesses of between 4-10 microns being common.

A plurality of p-type well implant regions 330 are formed in upper portions of the n-type drift region 320. The well implant regions 330 may be formed via ion implantation. Each well implant region 330 comprises a moderately-doped p-type well region 332 and a more heavily-doped p-type well contact region 338. As shown best in FIG. 8A, the well implant regions 330 may extend as stripes in a first direction (the y-direction in FIG. 8A), and may be spaced apart from each other in a second direction (here, the x-direction) that is perpendicular to the first direction. The well implant regions 330 extend to a predetermined depth into the drift region 320 in a third direction (here, the z-direction) that is perpendicular to both the first direction and the second direction. The well regions 332 are commonly referred to as “p-wells” when the well regions 332 are p-type regions, and this terminology will be used herein. The p-wells 332 may have a peak doping concentration of, for example, between 5×10¹⁵ cm⁻³ and 5×10¹⁹ cm⁻³ and, more typically, between 5×10¹⁶ cm⁻³ and 5×10¹⁹ cm⁻³. The p-wells 332 often have a doping concentration that varies with depth, with upper outer portions of each p-well 332 being less heavily doped than lower portions of the p-wells 332. Thus, each p-well 332 may have a graded p-type doping profile with the doping concentration increasing with increasing depth. As will be discussed in further detail below, the upper outer regions of each p-well 332 act as channel regions 333 during on-state operation, and the doping concentration of the channel regions 333 is typically selected based on various performance characteristics of the power MOSFET, including a desired on-state resistance value. The lower portions of the p-wells 332 are typically more heavily doped p-type than the channel regions 333 to enhance the electric field blocking properties of the well implant regions 330. Note that references herein to the “depth” of various regions within a semiconductor structure refer to the distance that the elements extend downwardly from an upper surface of the semiconductor structure into the semiconductor structure.

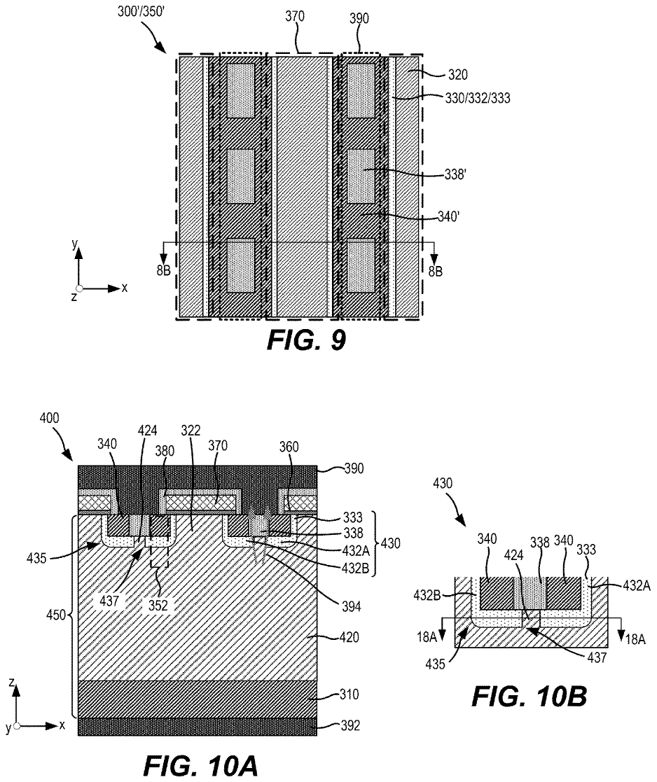

Heavily-doped n-type silicon carbide source regions 340 are formed in upper portions of the well implant regions 330. The source regions 340 may have a doping concentration of, for example, between 5×10¹⁸ cm⁻³ and 5×10²¹ cm⁻³. The source regions 340 are typically formed via ion implantation. In the depicted embodiment, the source regions 340 each extend as stripes in the y-direction, with two source regions 340 formed in each well implant region 330. Other implementations are possible as shown, for example, in FIG. 9, which is discussed below.

As discussed above, a heavily-doped p-type well contact region 338 is formed in each p-well 332. Each well contact region 338 may be formed in between the two source regions 340 that are provided in each well implant region 330. Each well contact region 338 may extend to the upper surface of the semiconductor structure 350 and may have a peak doping concentration that is higher than the peak doping concentration of the p-well 332. Each well contact region 338 may have a peak doping concentration of, for example, about 1×10¹⁹/cm³ to 1×10²¹ cm³, such as, for example, about 5×10¹⁹/cm³ to 5×10²⁰ cm³ or about 5×10¹⁹/cm³ to 1×10²⁰ cm³. Each well contact region 338 may directly contact the one or more p-wells 332 that are part of the well implant region 338 that includes the well contact region 338. Since the well contact regions 338 extend to the upper surface of the semiconductor structure 350, they may directly contact the source metallization 390 (discussed below), thereby forming low resistivity connections between the p-wells 332 and the source metallization 390.

The well implant regions 330 included in power MOSFET 300 each include a p-well 332, a well contact region 338, with the well contact region interposed in between the two source regions 340. It will be appreciated, however, that embodiments of the present invention are not limited thereto. For example, in other embodiments, a single source region 340′ may be provided in each well implant region 330, and a plurality of well contact regions 338′ may be provided that appear as “islands” in the single source region 340′ when the semiconductor structure of the power MOSFET is viewed from above, as shown in FIG. 9. As another example, the source regions 340′ and well contact regions 338′ may be formed as short “stripes” that extend in the x-direction.

Referring again to FIG. 8B, the drift region 320 extends to the upper surface of the semiconductor structure 350 in between each pair of adjacent well implant regions 330. The portions of the drift region 320 that are in between adjacent pairs of well implant regions 330 are referred to as JFET regions 322. In some cases, the JFET regions 322 may be more heavily doped than the remainder of the drift region 320.

Similar to conventional power MOSFET 1, power MOSFET 300 includes a plurality of parasitic n-p-n BJTS 352 that are formed where portions of the p-wells 332 are interposed in between and directly contact the n-type drift region 320 on one side and the n-type source region 340 on the other side. One of the parasitic BJTS 352 is shown in FIG. 8B in the dashed box labelled 352. The parasitic BJT 352 is not controlled by the gate terminal, and hence once turned on it is an uncontrollable current path.

The substrate 310, the drift region 320 (including the JFET regions 322), the well implant regions 330 (including the p-wells 332 and the well contact regions 338), and the source regions 340 together comprise the semiconductor structure 350 of power MOSFET 300. FIG. 8A is a plan (top-down) view of a small portion of the semiconductor layer structure 350.

As shown in FIG. 8B, a plurality of gate dielectric layers 360 are formed on the upper surface of the semiconductor structure 350. Each gate dielectric layer 360 may comprise, for example, a silicon oxide layer, although other insulating materials may be used. A plurality of gate electrodes 370 are formed on the respective gate dielectric layers 360. Each gate electrode 370 may comprise, for example, a conductive material such as polysilicon, a silicide or a metal. A plurality of intermetal dielectric layers 380 may cover the respective gate electrode layers 370. Each intermetal dielectric layer 380 may comprise, for example, a silicon oxide layer. The gate dielectric layers 360, the gate electrodes 370 and the intermetal dielectric layers 380 extend on top of the semiconductor structure 350 as stripes in the y-direction. The upper surface of the semiconductor structure 350 (and, more particularly, the well contact regions 338 and the source regions 340) is exposed between each pair of adjacent gate structures 370. A source metallization 390 is formed over the intermetal dielectric layer 380 and on the exposed portions of the semiconductor structure 350 so that the source metallization 390 makes physical and electrical contact to the n-type source regions 340 and the p-type well contact regions 338 while being electrically insulated from the gate electrode 370. The source metallization 390 may comprise, for example, metals such as nickel, titanium, tungsten and/or aluminum, and/or alloys and/or thin layered stacks of these and/or similar materials and may include one or more bulk metal layers. The source metallization 390 may also include a silicide layer that directly contacts the semiconductor layer structure to form an ohmic contact. A drain contact 392 may be formed on the lower surface of the substrate 310. The drain contact 392 may comprise, for example, the same or similar materials to the source metallization layer 390, and may form an ohmic contact to the silicon carbide substrate 310.

Comparing FIGS. 1B and 8B, it can be seen that the p-wells 332 in MOSFET 300 have a different shape than the p-wells 32 in conventional power MOSFET 1. In particular, the conventional p-wells 32 have sharp lower corners 35 and a bottom surface that extends to a relatively constant depth into the semiconductor structure 50. In contrast, the p-wells 332 of power MOSFET 300 have a main section 334 that has rounded outer lower corners 335 and a center section of each p-well 332 extends farther into the drift region 320 than does the outer regions of each p-well 332, so that each p-well 332 includes a downwardly-extending shield region 336. The lower corners 337 of each downwardly-extending shield region 336 may be sharper than the lower outer corners 335 of the main portions 334 of the p-wells 332. Herein, a first corner is considered to be “sharper” than a second corner if the interior angle defined by the first corner (here the interior angle defined by the bottom surface and side surface of p-well 332) is less than the interior angle defined by the second corner. For corner regions that are rounded as opposed to being defined by two intersecting straight segments, the rounded corner having the smaller radius of curvature is the sharper corner. A rounded corner is always less sharp than a corner formed by two straight line segments.

The “corners” shown in FIGS. 1B and 8B are corners that are present in lateral cross-sectional views of the depicted semiconductor devices. For power semiconductor devices having stripe configurations, a lateral cross-sectional view refers to a view taken through the device in the x-z plane shown in the figures, where the z-direction is the depth direction of the semiconductor device, which is the direction in which the epitaxial layers of the semiconductor structure are grown, and the x-direction is a direction that is perpendicular to both the z-direction and the longitudinal direction of the striped structures such as the gate electrodes, the well implant regions, etc. (i.e., the y-direction in the figures). The well implant regions 30, 330 shown in FIGS. 1B and 8B are three dimensional structures and thus the interfaces between the sidewalls and the lower surface of each well implant region 30, 330 is an edge. Typically, the sidewalls and the lower surface of each well implant region 30, 330 will have the same profile along their entire length, and thus the sharpness of the corners as shown in a lateral cross-sectional view apply along the full length of the well implant regions 30, 330.

Since the downwardly-extending shield regions 336 in power MOSFET 300 of FIG. 8B have sharper corners 337 than do the lower corners 335 of the main portion 334 of each p-well 332, during reverse blocking operation, electric field crowding effects will result in the electric fields at the lower corners 337 of the downwardly-extending shield regions 336 being higher than the electric fields at the lower corners 335 of the main portions 334 of the p-wells 332. As such, when avalanche currents are induced in power MOSFET 300, the electron-hole pairs will tend to start ionizing adjacent the lower corners 337 of the downwardly-extending shield regions 336. As such, the avalanche current will tend to flow along the paths shown by the bold arrows labelled 394 in FIG. 8B (in all of the figures, the bold arrow(s) 394 illustrating the avalanche current paths are only shown for one of the well implant regions as they tend to obscure the drawing). Notably, the avalanche current is directed away from the portion of the p-wells 332 that forms the base of the parasitic BJT 352. As such, power MOSFET 300 may exhibit improved ruggedness in that it can withstand higher voltage transients without a thermal runaway event occurring.

As shown in FIG. 8B, the “inner” sidewalls of the source regions 340 (i.e., the sidewalls that contact the well contact regions 338) may be aligned with sidewalls of the downwardly-extending shield regions 336 in some embodiments. In other embodiments, a lateral width (i.e., the width in the x-direction) of each downwardly-extending shield region 336 may be less than a width of the well contact region 338 that it vertically overlaps, so that the source regions 340 will not have any vertical overlap with the downwardly-extending shield regions 336. Such a design may further reduce the amount of avalanche current that flows into the lower outer corners 335 of the p-wells 332.

While power MOSFET 300 is designed to reroute the avalanche current to a more favorable location, power MOSFET 300 may not appreciably shorten the current path through the higher resistance p-wells 332 since the avalanche current will flow through the downwardly-extending shield regions 336.

In example embodiments, the lateral width of each source region 340 may be between 1.5 and 3 microns, and a depth of each source region 340 may be between 0.3 and 1.0 microns. The lateral width of each well implant region 330 may be between 4 and 8 microns, and a depth of each well implant region 330 may be between 0.6 and 1.6 microns. A lateral width of each downwardly-extending shield region 336 may be less than a lateral width of the well implant region 330 but otherwise is not limited. The depth of each downwardly-extending shield region 336 from a lower surface of the p-well 332 may be between 1 and 2 microns. As the depth of the downwardly-extending shield region 336 is increased, the distance between the downwardly-extending shield region 336 and the substrate 310 is decreased, which acts to increase the electric field levels during reverse blocking operation at the junction between the drift region 320 and the downwardly-extending shield region 336. This increase in the electric field levels may further facilitate directing most of the avalanche to flow along the paths shown by the arrows labelled 394 in FIG. 8B. In one example embodiment, each source region 340 may have a lateral width of about 2 microns and a depth of about 0.5 microns, the well implant regions 330 may have lateral widths of about 6 microns and depths of about 1 micron, and the downwardly-extending shield region 336 may have depths from the lower surface of the p-wells 332 of about 1.3-1.5 microns.

Still referring to FIGS. 8A-8B, pursuant to some embodiments of the present invention, semiconductor devices such as power MOSFET 300 are provided that comprise a semiconductor structure 350 that comprises a drift region 320 having a first conductivity type, a well region 332 having a second conductivity type on the drift region 320, a source region 340 having the first conductivity type on the well region 332, and a well contact region 338 having the second conductivity type on the well region 332, the well contact region 338 having a higher doping concentration than the well region 332. The well region 332 and the well contact region 338 may both be part of a well implant region 330 that has the second conductivity type. The semiconductor device 300 further comprises a gate electrode 370 on the semiconductor structure 350 that vertically overlaps the source region 340. In a lateral cross-section of the semiconductor device 300, a first side of the well region 332 comprises a first lower corner 335 and a second lower corner 337, where the second lower corner 337 is farther away from the gate electrode 370 than is the first lower corner 335 and/or is closer to the well contact region 338 than the first lower corner 335. The second lower corner 337 may also be farther from the upper surface of the semiconductor structure 350 than is the first lower corner 335. Moreover, the second lower corner 337 is a sharper corner than the first lower corner 335. The semiconductor device 300 may be configured that during reverse blocking operations the electric field level at the second lower corner 337 is higher than the electric field level at the first lower corner 335.

In some embodiments, the first lower corner 335 may be a rounded corner having a first radius of curvature and the second lower corner 337 may be a rounded corner having a second radius of curvature that is smaller than the first radius of curvature. In some embodiments, the second lower corner may be a lower corner of a downwardly-extending shield region 336 of the well region 332, and the source region 340 may not vertically overlap the shield region 336.

FIG. 10A is a schematic cross-sectional view of a power MOSFET 400 according to further embodiments of the present invention. The upper surface of the semiconductor structure 450 of power MOSFET 400 may appear the exact same as the upper surface of the semiconductor structure 350 of power MOSFET 300, and hence the view of FIG. 8A applies equally to power MOSFET 200. The cross-sectional view of FIG. 10A is taken along line 8B-8B of FIG. 8A. FIG. 10B is a greatly enlarged view of one of the well implant regions 430 shown in FIG. 10A.

As can be seen by comparing FIGS. 1B and 10A, power MOSFET 400 is similar to conventional power MOSFET 1, with the one difference being that each well implant region 430 in power MOSFET 400 comprises first and second spaced-apart p-wells 432A, 432B as opposed to the single p-well 32 that is included in each well implant region 30 of power MOSFET 1. Pairs of p-wells 432A, 432B may be formed by adding an implant mask on the semiconductor structure 450 that partially covers the region where the well contact regions 338 will be formed during an ion implantation step that is performed to form the p-wells 432A, 432B. The implant mask (not shown) results in the ion implantation process forming first and second spaced-apart p-wells 432A, 432B in the position of each conventional p-well 32 in power MOSFET 1. Thereafter, a second ion implantation process may be performed to form a source region 340 in each p-well 432A, 432B. A third ion implantation step may be performed to form the well contact regions 338. It should be noted that the three above-described ion implantation steps may be performed in any order.

As shown best in the enlarged view of FIG. 10B, the drift region 420 of power MOSFET 400 includes a plurality of upwardly-extending portions 424 that extend in between the lower portions of the respective spaced-apart pairs of p-wells 432A, 432B. JFET regions 322 are provided in between adjacent well implant regions 430. Each upwardly-extending portion 424 of the drift region 420 may have a first sidewall that directly contacts a sidewall of the first p-well 432A, a second sidewall that directly contacts a sidewall of the second p-well 432B, and a top surface that directly contacts a bottom surface of the well contact region 338. In addition, the lower surface of each well contact region 338 may be in direct contact with each of the p-wells 432A, 432B in each spaced-apart pair of p-wells 432A, 432B so that the combination of the two p-wells 432A, 432B and a respective one of the well contact regions 338 together form a continuous well that isolates the source regions 340 from the underlying drift region 420.

The design of the well implant region 430 shown in FIGS. 10A-10B may improve the ruggedness of power MOSFET 400 as compared to conventional power MOSFET 1 of FIGS. 1A-1B. In particular, the lower corner 435 of each p-well 432A, 432B that faces an adjacent JFET region 322 is rounded, while the other lower corner 437 of each p-well 432A, 432B is a sharp corner that faces away from the adjacent (closest) JFET region 322. As such, when avalanche currents are induced in power MOSFET 400, the electron-hole pairs will tend to start ionizing adjacent the lower corners 437 of the p-wells 432A, 432B that are underneath the well contact regions 338 before they start ionizing adjacent the lower corners 435 that face the JFET regions 322. As such, the avalanche current will tend to flow along the paths shown by the bold arrows labelled 394 in FIG. 10A.

Power MOSFET 400 may exhibit improved ruggedness as compared to conventional power MOSFET 1 for two reasons. First, by configuring the p-wells 432A, 432B to have sharp lower corners 437 underneath the well contact regions 338 and softer (less sharp) lower corners 435 adjacent the JFET regions 322, the avalanche currents are mostly redirected away from the portions of the p-wells 432A, 432B that act as the bases of the parasitic BJTS 352. Second, the avalanche current paths through the p-wells 432A, 432B are shortened since lateral avalanche current flow through the p-wells 432A, 432B is largely eliminated.

In power MOSFET 400, the source regions 340 and the well contact regions 338 extend to approximately the same depth in the semiconductor structure 450. It will be appreciated that embodiments of the present invention are not limited thereto. As will be explained below with reference to FIGS. 14-17, in some cases it may be advantageous to have the well contact regions 338 extend deeper into the semiconductor structure 450 than the source regions 340, and deeper than the p-wells 432A, 432B as well. In other cases, it may be advantageous to have the source regions 340 extend deeper into the semiconductor structure 450 than the well contact regions 338, since this will reduce the extent to which the well contact region 338 shields the lower corners 437 of the p-wells 432A, 432B that are underneath the well contact region 338 from high electric field values during reverse blocking operation. By allowing the electric fields to increase in this region, the avalanche currents may be drawn away from the base of the parasitic BJT 352.

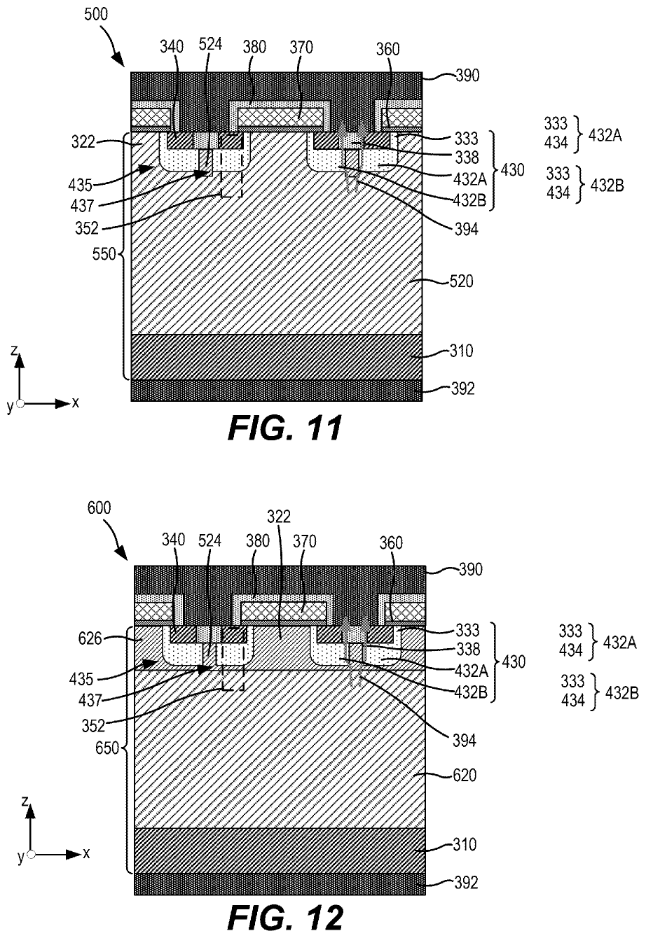

FIG. 11 is a schematic cross-sectional view of a power MOSFET 500 according to further embodiments of the present invention. Power MOSFET 500 includes a semiconductor structure 550. The upper surface of semiconductor structure 550 may appear the exact same as the upper surface of the semiconductor structure 350 of power MOSFET 300, and hence the view of FIG. 8A applies equally to power MOSFET 500. The cross-sectional view of FIG. 11 corresponds to a cross-section along line 8B-8B of FIG. 8A.

As can be seen by comparing FIGS. 10A and 11, power MOSFET 500 may be identical to power MOSFET 400, with the one difference being that the upwardly-extending portions 424 of the drift region 420 of power MOSFET 400 are replaced with n-type electric field concentration regions 524 that have a higher doping concentration than the drift region 520. Each n-type electric field concentration region 524 may have a first sidewall that directly contacts a sidewall of the first p-well 432A, a second sidewall that directly contacts a sidewall of the second p-well 432B, and a top surface that directly contacts a bottom surface of the well contact region 338. The lower surface of each n-type electric field concentration region 524 may extend below the lower surfaces of the p-wells 432A, 432B, as shown, or alternatively may be coplanar with the lower surfaces of the p-wells 432A, 432B, or may not extend as deep into the semiconductor structure as the lower surfaces of the p-wells 432A, 432B. The electric field concentration regions 524 may be formed by ion implantation. By replacing the upwardly-extending portions 424 of the drift region 420 of power MOSFET 400 with n-type electric field concentration regions 524 that have a higher doping concentration than the drift region 520, the electric field levels during reverse blocking operation adjacent the bottom surface of each electric field concentration region 524 may be increased, thereby increasing the electric fields adjacent the lower corners 437 of the p-wells 432A, 432B that face away from the JFET regions 322. This further helps redirect the avalanche currents away from the lower outer corners 435 of the p-wells 432A, 432B. As shown in FIG. 11, the avalanche current flow in power MOSFET 500 is very similar to the avalanche current flow in power MOSFET 400, as shown by the bold red arrows 394.

FIG. 12 is a schematic cross-sectional view of a power MOSFET 600 according to further embodiments of the present invention. Power MOSFET 600 includes a semiconductor structure 650. The upper surface of semiconductor structure 650 may appear the exact same as the upper surface of the semiconductor structure 350 of power MOSFET 300, and hence the view of FIG. 8A applies equally to power MOSFET 600. The cross-sectional view of FIG. 12 corresponds to a cross-section along line 8B-8B of FIG. 8A.

Power MOSFET 600 is similar to power MOSFET 500, with the one difference being that the upper portion of the drift region 620 of power MOSFET 600 is formed as a more highly doped current spreading layer 626. The electric field concentration regions 324 of power MOSFET 500 are included in power MOSFET 600, although in power MOSFET 600 they may be formed as part of the current spreading layer 626 (i.e., may have the same doping concentration as the current spreading layer 626). The avalanche currents may flow in power MOSFET 600 in the same fashion as they flow in power MOSFET 500.

Since the current spreading layer 626 is present around the lower outer corners 435 of each p-well 432A, 432B, the current spreading layer 626 acts to increase the electric field levels adjacent both the lower corners 435 that face the adjacent JFET region 322 and the lower corners 437 that face away from the adjacent JFET region 322. As such, adding the current spreading layer 626 alone may do little if anything to redirect avalanche currents away from the base of the parasitic BJT 352. Thus, in power MOSFET 600, either the n-type doping concentration of the portion of the current spreading layer 626 that is in between each facing pair of p-wells 432A, 432B should be increased beyond the doping concentration of the current spreading layer 626 and/or the lower corners 437 of each p-well 432A, 432B that face away from the adjacent JFET region 322 should be made to be sharper than the lower corners 435 of each p-well 432A, 432B that face from the adjacent JFET region 322. As shown in FIG. 12, the avalanche current flow in power MOSFET 600 is very similar to the avalanche current flow in power MOSFET 400, as shown by the bold red arrows 394.

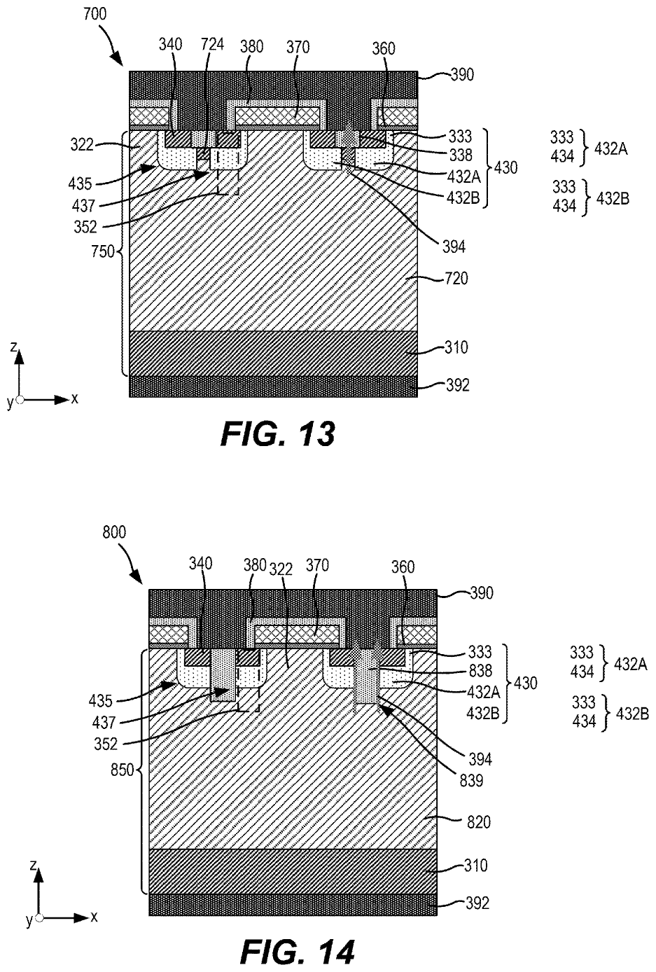

FIG. 13 is a schematic cross-sectional view of a power MOSFET 700 according to further embodiments of the present invention. Power MOSFET 700 includes a semiconductor structure 750. The upper surface of semiconductor structure 750 may appear the exact same as the upper surface of the semiconductor structure 350 of power MOSFET 300, and hence the view of FIG. 8A applies equally to power MOSFET 700. The cross-sectional view of FIG. 13 corresponds to a cross-section along line 8B-8B of FIG. 8A.

Power MOSFET 700 is similar to power MOSFET 500, with the one difference being that the moderately doped n-type electric field concentration region 524 included in the upper portion of the drift region 620 of power MOSFET 600 is replaced with a highly doped n-type electric field concentration region 724. In the depicted embodiment, the highly doped n-type electric field concentration region 724 is shorter in the depth direction than the electric field concentration region 524 of power MOSFET 500 so that the highly doped n-type electric field concentration region 724 does not extend as deeply into the semiconductor structure 750 as the p-wells 432A, 432B. A p-n junction in a power semiconductor device breaks down more quickly when the junction is between a heavily-doped p-type region and a lightly-doped n-type region. Power MOSFET 700 provides such a p-n junction at the interface between the well contact region 338 and the highly doped n-type electric field concentration region 724. As shown by the bold arrow labelled 394 in FIG. 13, the avalanche currents will flow directly from the highly doped n-type electric field concentration regions 724 to the well contact regions 338, thereby almost or completely bypassing the p-wells 432A, 432B. This acts to significantly decrease the voltage drop along the avalanche current path, both because the length of the avalanche current path is shortened and because the avalanche current paths flow almost exclusively through the more highly doped well contact regions 338, thereby avoiding the lower doped p-wells 432A, 432B that have a much higher resistance (and hence associated voltage drop).

Referring to FIGS. 11-13, pursuant to some embodiments of the present invention, semiconductor devices 500, 600, 700 are provided that comprise a semiconductor structure 550, 650, 750 that comprises a drift region 520, 620, 720 having a first conductivity type, a well implant region 430 having a second conductivity type on the drift region 520, 620, 720, the well implant region 430 including at least a first well region 432A and a well contact region 338 that has a higher doping concentration than the first well region 432A, a source region 340 having the first conductivity type on the first well region 432A and directly contacting the well contact region 338, and a selectively implanted electric field concentration region 524, 724 having the first conductivity type underneath the well contact region 338 and directly contacting a sidewall of the first well region 432A.

In some embodiments, the electric field concentration region 524, 724 has a higher doping concentration than the drift region 520, 620, 720. The semiconductor structure 550, 650, 750 may also comprise a second well implant region 430 that has the second conductivity type on the drift region 520, 620, 720, a second source region 340 that has the first conductivity type in the second well implant region 430, and a JFET region 322 that has the first conductivity type in between the first well implant region 430 and the second well implant region 430, where the electric field concentration region 524, 724 has a higher doping concentration than the JFET region 322. In such embodiments, the device may further comprise a gate electrode 370 on the semiconductor structure 550, 650, 750, the gate electrode 370 vertically overlapping the JFET region 322 and the first and second well implant regions 430. The first well region 430 may include a first lower corner 435 that faces the JFET region 322 and a second lower corner 437 that faces away from the JFET region 322. The second lower corner 437 may be sharper than the first lower corner 435. This may help ensure that during reverse blocking operations the electric field level at the second lower corner 437 is higher than the electric field level at the first lower corner 435. In some embodiments, a lower portion of the well contact region 338 may directly contact the electric field concentration region 524, 724. In some embodiments, the lower portion of the well contact region 338 may directly contact the first well region 432A.

The electric field concentration region 524, 724 may have a doping concentration that is greater than a doping concentration of the drift region 520, 620, 720. In some embodiments, the electric field concentration region 524, 724 extends deeper into the semiconductor structure 550, 650, 750 than does the first well region 432A. In some embodiments, the doping concentration of the electric field concentration region 524, 724 is less than a doping concentration of the source region 340. In some embodiments, the first well region 432A extends deeper into the semiconductor structure 550, 650, 750 than does the electric field concentration region 524, 724, and the doping concentration of the electric field concentration region 524, 724 exceeds the doping concentration of the first well region 432A.

FIG. 14 is a schematic cross-sectional view of a power MOSFET 800 according to further embodiments of the present invention. Power MOSFET 800 includes a semiconductor structure 850. The upper surface of semiconductor structure 850 may appear the exact same as the upper surface of the semiconductor structure 350 of power MOSFET 300, and hence the view of FIG. 8A applies equally to power MOSFET 800. The cross-sectional view of FIG. 14 corresponds to a cross-section along line 8B-8B of FIG. 8A.

Power MOSFET 800 is similar to power MOSFET 400, with the major difference being that in power MOSFET 800 the heavily doped well contact regions 838 extend much more deeply into the semiconductor structure 850 than do the moderately doped well contact regions 338 that are included in power MOSFET 400. As shown in FIG. 14, the well contact regions 838 extend deeper into the semiconductor structure 850 than the p-wells 432A, 432B so that a p-n junction is formed between the highly-doped p-type well contact region 838 and the lightly-doped n-type drift region 820. The electric field at this p-n junction will tend to be high during reverse blocking operation, so that avalanche breakdown will occur adjacent this p-n junction. Additionally, the lower corners 839 of the well contact regions 838 that directly contact the drift region 820 may be formed as sharp corners, while the lower corners 435 of the p-wells 432A, 432B may be rounded corners. This may also help ensure that the avalanche currents will primarily flow into the well contact regions 838 instead of flowing into the well regions 432A, 432B. As shown by the bold arrow labelled 394 in FIG. 14, since the avalanche currents arise at the interface between the heavily doped well contact regions 838 and the drift region 820, the avalanche current will generally be directed away from the p-wells 432A, 432B. Since the well contact regions 838 are more highly doped than the p-wells 432A, 432B, the amount of voltage drop that occurs in response to the avalanche current may be reduced. All of the above-discussed features of power MOSFET 800 may improve its ruggedness.

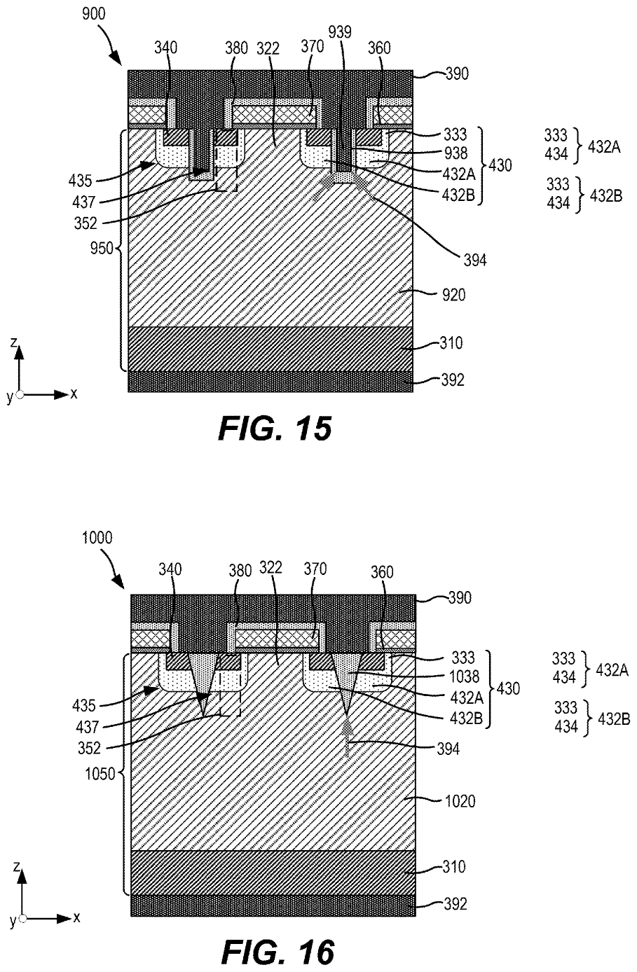

FIG. 15 is a schematic cross-sectional view of a power MOSFET 900 according to still further embodiments of the present invention. Power MOSFET 900 includes a semiconductor structure 950. The upper surface of semiconductor structure 950 may appear the exact same as the upper surface of the semiconductor structure 350 of power MOSFET 300, and hence the view of FIG. 8A applies equally to power MOSFET 900. The cross-sectional view of FIG. 15 corresponds to a cross-section along line 8B-8B of FIG. 8A.

Power MOSFET 900 is identical to power MOSFET 800 except that in power MOSFET 900, the well contact region 938 includes a central recess 939 that extends in the longitudinal direction (i.e., the y-direction) so that the source metallization 390 may extend into the recess 939. Since the source metallization 390 extends into the semiconductor structure 950, the distance that the avalanche current must travel through the well contact region 938 before reaching the very low resistance source metallization 390 is reduced. This shortens the avalanche current path, thereby decreasing the voltage drop along the avalanche current path. As discussed above, this acts to further improve the ruggedness of power MOSFET 900. The recesses 939 in the well contact regions 938 also increase the contact area between the source metallization 390 and the well contact regions 938, which can also advantageously reduce the on-state resistance of power MOSFET 900.

FIG. 16 is a schematic cross-sectional view of a power MOSFET 1000 according to further embodiments of the present invention. Power MOSFET 1000 includes a semiconductor structure 1050. The upper surface of semiconductor structure 1050 may appear the exact same as the upper surface of the semiconductor structure 350 of power MOSFET 300, and hence the view of FIG. 8A applies equally to power MOSFET 1000. The cross-sectional view of FIG. 16 corresponds to a cross-section along line 8B-8B of FIG. 8A.

Power MOSFET 1000 is similar to power MOSFET 800, with the one difference being that in power MOSFET 1000 the highly-doped well contact region 1038 has a triangular shape so the portion thereof that extends into the drift region 1020 has a very sharp corner that has an acute interior angle. The sharper angle at the bottom of the well contact region 1038 may cause increased electric field crowding effects so that the electric fields during reverse blocking operation at the bottom of well contact region 1038 will be even higher than the electric field levels at the lower corners 839 of well contact region 838 of power MOSFET 800.

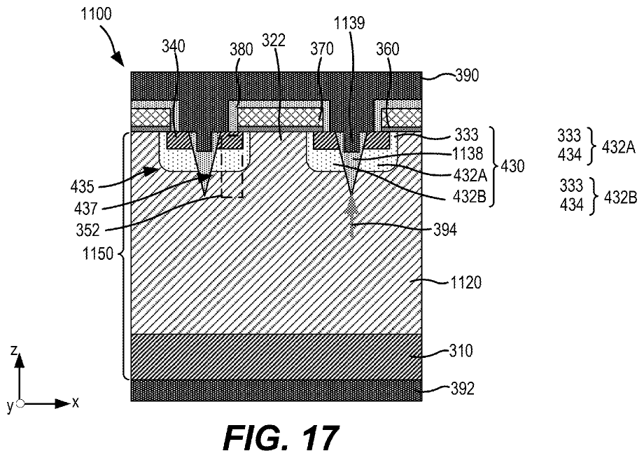

FIG. 17 is a schematic cross-sectional view of a power MOSFET 1100 according to yet additional embodiments of the present invention. Power MOSFET 1100 includes a semiconductor structure 1150. The upper surface of semiconductor structure 1150 may appear the exact same as the upper surface of the semiconductor structure 350 of power MOSFET 300, and hence the view of FIG. 8A applies equally to power MOSFET 1100. The cross-sectional view of FIG. 17 corresponds to a cross-section along line 8B-8B of FIG. 8A.

Power MOSFET 1100 is identical to power MOSFET 1000 except that in power MOSFET 1100, the well contact region 1138 includes a central recess 1139 that extends in the longitudinal direction (i.e., the y-direction) so that the source metallization 390 may extend into the recess 1139. This decreases the amount that the avalanche current must travel through the well contact region 1138 before reaching the very low resistance source metallization 390. This shortens the avalanche current path, thereby further improving the ruggedness of power MOSFET 1100.

Referring to, for example, FIGS. 10A-17, pursuant to some embodiments of the present invention, semiconductor devices 400, 500, 600, 700, 800, 900, 1000, 1100 are provided that comprise a semiconductor structure 450, 550, 650, 750, 850, 950, 1050 that comprises a drift region 420, 520, 620, 720, 820, 920 having a first conductivity type, a well region 432A, 432B that has a second conductivity type on the drift region 420, 520, 620, 720, 820, 920, 1020, a source region 340 having the first conductivity type on the well region 432A, 432B, and a well contact region 338, 838, 938, 1038, 1138 having the second conductivity type on the well region 432A, 432B, the well contact region 338, 838, 938, 1038, 1138 having a higher doping concentration than the well region 432A, 432B. A lower portion of the well contact region 338, 838, 938, 1038, 1138 directly contacts a portion of the semiconductor structure 450, 550, 650, 750, 850, 950 that has the first conductivity type.

The semiconductor device 400, 500, 600, 700, 800, 900, 1000, 1100 further comprises a gate dielectric layer 360 on an upper surface of the semiconductor structure 450, 550, 650, 750, 850, 950 and a gate electrode 370 on the gate dielectric layer 360 opposite the semiconductor structure 450, 550, 650, 750, 850, 950. A channel region 333 is provided in an upper portion of the well region 432A, 432B and the well region 432A, 432B directly contacts both the source region 340 and the well contact region 338, 838, 938, 1038, 1138. The semiconductor device 400, 500, 600, 700, 800, 900, 1000, 1100 may also comprise a source metallization 390 on an upper surface of the semiconductor structure 450, 550, 650, 750, 850, 1050, where an upper surface of the well contact region 338, 838, 938, 1038, 1138 directly contacts the source metallization 390.

In some embodiments, the lower portion of the well contact region 338 may directly contact an electric field concentration region 524, 724 that has the first conductivity type, the electric field concentration region 524, 724 having a doping concentration that is greater than a doping concentration of the drift region 520, 620, 720. In some embodiments, the electric field concentration region 524 may extend deeper into the semiconductor structure 550, 650 than does the well region 432A, 432B. In these embodiments, the doping concentration of the electric field concentration region 524 may be less than a doping concentration of the source region 340. In other embodiments, the well region 432A, 432B may extend deeper into the semiconductor structure 750 than does the electric field concentration region 724, and the doping concentration of the electric field concentration region 724 may exceed the doping concentration of the well region 432A, 432B.

In some embodiments, the lower portion of the well contact region 338, 838, 938, 1038, 1138 may directly contact the drift region 420, 820, 1020. The well contact region 838, 938, 1038, 1138 may extend deeper into the semiconductor structure 450, 850, 1050 than does the well region 432A, 432B. In some embodiments, an upper surface of the semiconductor structure 850, 1050 may include a recess 939, 1139 that extends into the well contact region 938, 1138, and the source metallization 390 may extend into the recess 939, 1139. In some embodiments, the lower portion of the well contact region 1038, 1138 may include a corner 1039, 1139 having an internal angle that is less than 90° in a lateral cross-section of the device.

As shown in FIG. 12, in some embodiments the semiconductor structure 650 may further comprise a current spreading layer 626 that has the first conductivity type on the drift region 620, where the current spreading layer 626 has a doping concentration that is higher than a doping concentration of the drift region 620. The lower portion of the well contact region 338 may directly contact the current spreading layer 626 in these embodiments. The current spreading layer 626 may, but need not, extend deeper into the semiconductor structure 650 than does the well region 432A, 432B.

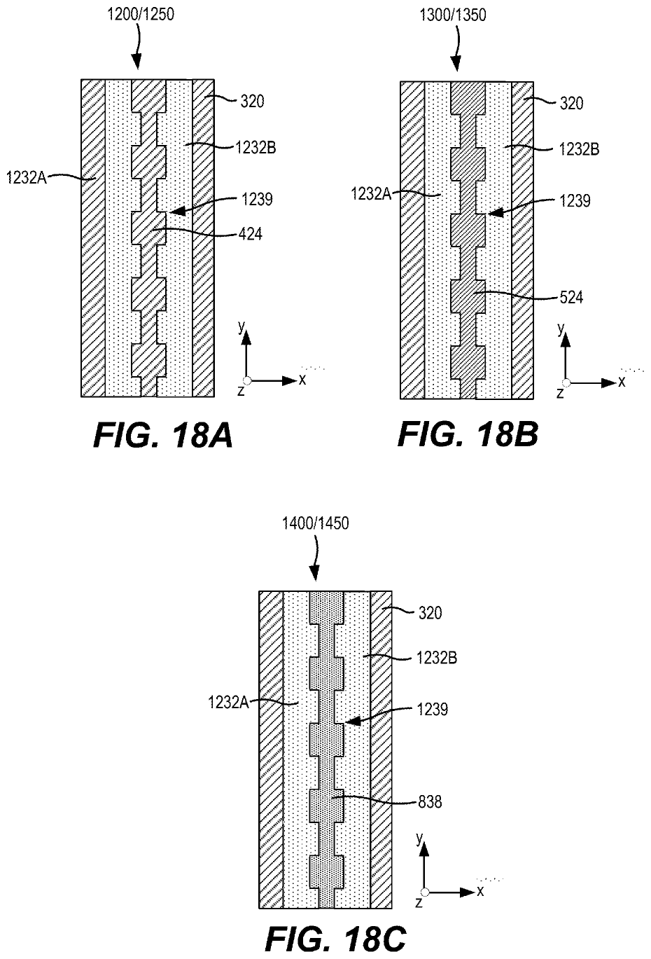

FIG. 18A is a schematic horizontal cross-sectional view taken through the semiconductor structure 1250 of a power MOSFET 1200 according to further embodiments of the present invention. Power MOSFET 1200 is a modified version of power MOSFET 400 of FIGS. 10A-10B. The cross-sectional view shown in FIG. 18A is taken along a plane that is parallel to the upper surface of the semiconductor substrate 310 and at a depth that is just slightly above the lower surfaces of the p-wells 432A, 432B and below the lower surface of the well contact region 338. Line 18A-18A in FIG. 10B shows the location of the cross-section of FIG. 18A.

As shown in FIG. 18A, the difference between power MOSFET 1200 and power MOSFET 400 is that in power MOSFET 1200 each p-well 1232A, 1232B has a width that varies along the longitudinal direction (y-direction) of the p-well 1232A, 1232B, whereas the p-wells 432A, 432B of power MOSFET 400 have constant lateral widths By varying the widths of the p-wells 1232A, 1232B a plurality of three dimensional lower corners 1239 are created. Such three-dimensional lower corners 1239 act to concentrate electric fields more than two dimensional corners, and hence the design of p-wells 1232A, 1232B may be even more effective in inducing the avalanche currents to arise in portions of the p-wells p-well 1232A, 1232B that are underneath the well contact region 338 so that the avalanche currents are directed away from the bases of the above-described parasitic BJTS.

FIG. 18B is a schematic horizontal cross-sectional view taken through the semiconductor structure 1350 of a power MOSFET 1300 according to still further embodiments of the present invention. Power MOSFET 1300 is a modified version of power MOSFET 500 of FIG. 11, and is taken along the same cut line as FIG. 18A. As is readily apparent, power MOSFET 1300 makes the same modification to the shape of the p-wells that is made in power MOSFET 1200 of FIG. 18A, and the only difference between power MOSFET 1200 and power MOSFET 1300 is that power MOSFET 1300 has an electric field concentration region 524 in between the two adjacent p-wells 1232A, 1232B instead of the drift region 424 being in the gap between adjacent p-wells as is the case in power MOSFET 1200. It will be appreciated that power MOSFETS 600 and 700 of FIGS. 12 and 13 may be modified in the same manner as shown in FIG. 18B to provide additional embodiments.

FIG. 18C is a schematic horizontal cross-sectional view taken through the semiconductor structure 1450 of a power MOSFET 1400 according to yet additional embodiments of the present invention. Power MOSFET 1400 is a modified version of power MOSFET 800 of FIG. 14, and is taken along the same cut line as FIG. 18A. Power MOSFET 1400 makes the same modification to the shape of the p-wells that is made in power MOSFET 1200 of FIG. 18A, and the only difference between power MOSFET 1200 and power MOSFET 1400 is that power MOSFET 1400 has the well contact region 838 in between the two adjacent p-wells 1232A, 1232B instead of the drift region 424 being in the gap between adjacent p-wells as is the case in power MOSFET 1200. It will be appreciated that power MOSFETS 900, 1000 and 700 of FIGS. 15-17 may be modified in the same manner as shown in FIG. 18C to provide additional embodiments.

As can be seen from FIGS. 18A-18C, pursuant to some embodiments of the present invention, semiconductor devices 1200, 1300, 1400 are provided that comprise a semiconductor structure that comprises a drift region 320 having a first conductivity type, a well implant region that has a second conductivity type on the drift region 320, the well implant region comprising first and second well regions 1232A, 1232B and a well contact region on the first and second well regions 1232A, 1232B and having a higher doping concentration than the first and second well regions 1232A, 1232B, and first and second source regions having the first conductivity type on the respective first and second well regions 1232A, 1232B. The well contact region has a longitudinal axis that extends in a first direction and the first and second well regions are spaced apparat from each other in a second direction that is perpendicular to the first direction. A width of the first well region 1232A in the second direction varies along a length of the first well region 1232A.

A width of the second well region 1232B in the second direction may also vary along a length of the second well region 1232B. In some embodiments, a portion 424 of the drift region 320 is positioned in between portions of the first and second well regions 1232A, 1232B. In other embodiments, an electric field concentration region 524, 724 that has a first conductivity type and a higher doping concentration than the drift region 320 is positioned in between portions of the first and second well regions 1232A, 1232B. In still other embodiments, the well contact region 838 extends deeper into the semiconductor structure in between portions of the first and second well regions 1232A, 1232B.

In the above description, MOSFETS having a stripe configuration have been described where the well implant regions extend as stripes in the semiconductor structure and the gate electrodes extend as stripes on an upper surface of the semiconductor structure. It will be appreciated, however, that embodiments of the present invention are not limited to these configurations. For example, any of the above-described power MOSFETS could be modified to include a so-called “mesh” gate electrode where gate electrodes are provided that extend in both the y-direction and in the x-direction so that the gate signal can be distributed from one gate electrode to another gate electrode. In addition, the same techniques described above with respect to power MOSFETS 300, 400, 500, 600, 700, 800, 900, 1000, 1100 and 1200 may be implemented in power MOSFETS that have a so-called cell configuration. Power MOSFETS that have a cell configuration have well regions that are often formed as spaced-apart islands within the semiconductor structure.

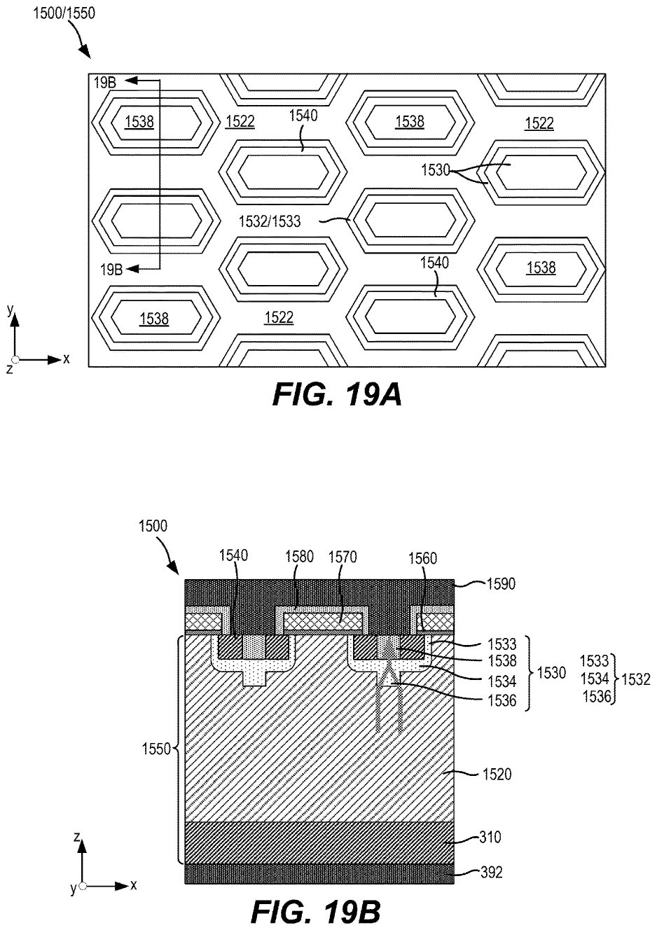

For example, FIGS. 19A-19B illustrate a power MOSFET 1500 according to further embodiments of the present invention that has a cell configuration. In particular, FIG. 19A is a plan (top) view of the semiconductor layer structure 1550 of a power MOSFET 1500 (i.e., the gate electrodes, upper dielectric layers and metallization layers are removed in the view of FIG. 19A), while FIG. 19B is a schematic cross-sectional view taken along line 19B-19B of FIG. 19A. As is well understood by those of skill in the art, a continuous gate electrode 1570 extends above the semiconductor layer structure 1550, covering the JFET regions 1522 of the drift region 1520 and also extending over the channel regions 1533 and the outer edges of the source regions 1540. The continuous gate electrode 1570 is separated from the semiconductor layer structure 1550 by a continuous gate oxide layer 1560 (see FIG. 19B).

As shown in FIGS. 19A-19B, well implant regions 1530 are formed in the upper surface of the semiconductor layer structure 1550. Each well implant region 1530 comprises a p-well 1532 and a well contact region 1538 that is formed in a central portion of the p-well 1532. The well implant regions 1530 each have an irregular hexagon shape when viewed from above, and the p-wells 1532 each have an irregular hexagonal ring shape when viewed from above. The well contact region 1538 also has a hexagonal shape when viewed from above. A source region 1540 having an irregular hexagonal ring shape when viewed from above is formed in the upper portion of each well implant region 1530 between the outer portion of the p-well 1532 and the well contact region 1538.

As noted above, FIG. 19B is a lateral cross-sectional view taken along line 19B-19B in FIG. 19A. As can be seen, the cross-section of FIG. 19B is identical to the cross-section of FIG. 8B. Thus, the description of FIG. 8B above applies equally to FIG. 19B, and hence FIG. 19B will not be described further here. It will be appreciated that any of the above-described “stripe” MOSFETS may be implemented alternatively as a cell MOSFET.

While power MOSFET 1500 has hexagonally-shaped cells (e.g., hexagonally-shaped well implant regions), it will be appreciated that embodiments of the present invention are not limited thereto, and that the principles of the present disclosure apply equally to MOSFETS having cell configurations with well implant regions having other shapes including, for example, MOSFETS having triangular, rectangular (e.g., square), and octagonal shaped well implant regions.

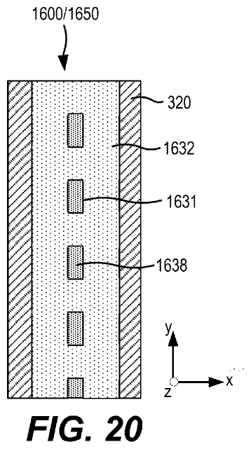

FIG. 20 is a schematic horizontal cross-sectional view taken through a semiconductor structure 1650 of a power MOSFET 1600 according to further embodiments of the present invention. The view of FIG. 20 corresponds to a small portion of an active region of power MOSFET 1600. FIG. 20 illustrates a modification that can be made to at least each of the above-discussed power MOSFETS 400, 500, 600, 700, 800, 900, 1000, 1100. The cross-sectional view shown in FIG. 20 is taken along a plane that is parallel to the upper surface of the semiconductor substrate 310 and at a depth that is just slightly above the lower surface of one of the p-wells 1632 and below the lower surface of the well contact region 1638.

Power MOSFET 1600 is a modified version of power MOSFET 800 of FIG. 14. As shown in FIG. 20, the difference between power MOSFET 1600 and power MOSFET 800 is that in power MOSFET 1600 each well implant region 1630 includes a single p-well 1632 as opposed to a pair of p-wells 432A, 432B, as was the case in power MOSFET 800. The single p-well 1632 has a plurality of openings 1631 formed therein, and the well contact region 1638 extends through each of the openings 1631 in the p-well 1632. The cross section of FIG. 14 accurately depicts power MOSFET 1600 so long as the cross-section is taken through one of the openings 1631 in the p-well 1632. It will be appreciated that any of the above-described embodiments that include pairs of p-wells in each well implant region can be modified in the same fashion as shown in FIG. 20.

As the above discussion makes clear, pursuant to embodiments of the present invention, semiconductor devices such as power MOSFETS are provided that comprise a semiconductor structure that includes a drift region having a first conductivity type, a well implant region that has a second conductivity type on the drift region, and a source region having the first conductivity type within the well implant region. The well implant region comprises a well region and a well contact region that has a higher doping concentration than the well region. The semiconductor structure is configured so that avalanche currents primarily flow into a central portion of a lower surface of the well implant region and may substantially bypass the portions of the well regions that form the base of the parasitic BJT.

While the above discussion focuses on n-channel MOSFETs, it will be appreciated that pursuant to further embodiments of the present invention, the polarity of each of the semiconductor layers in each device could be reversed so as to provide corresponding p-channel MOSFETs. Likewise, while the embodiments of the present invention discussed above are MOSFETs, it will be appreciated that the techniques disclosed herein may also be used to form insulated gate bipolar junction transistors (IGBTs) that include a MOSFET according to embodiments of the present invention, or other gate controlled power semiconductor devices.

Herein, embodiments of the present invention are described with respect to cross-sectional diagrams that show one or two unit cells of a power switching devices. It will be appreciated that actual implementations will typically include a much larger number of unit cells. However, it will also be appreciated that the present invention is not limited to such devices, and that the claims appended hereto also cover MOSFETs and other power switching devices that comprise, for example, a single unit cell. Moreover, while the present disclosure focuses on silicon carbide devices, it will be appreciated that embodiments of the present invention may also have applicability to devices formed using other wide band-gap semiconductors such as, for example, gallium nitride, zinc selenide or any other II-VI or III-V wide band-gap compound semiconductors.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1-29. (canceled)

30. A semiconductor device, comprising:
a semiconductor structure that comprises a drift region having a first conductivity type, a well implant region having a second conductivity type on the drift region, the well implant region including at least a first well region and a well contact region that has a higher doping concentration than the first well region, a source region having the first conductivity type on the first well region and directly contacting the well contact region, and a selectively implanted electric field concentration region having the first conductivity type underneath the well contact region and directly contacting a sidewall of the first well region.

31. The semiconductor device of claim 30, wherein the electric field concentration region has a higher doping concentration than the drift region.

32. The semiconductor device of claim 31, wherein the semiconductor structure further comprises a second well implant region that has the second conductivity type on the drift region, a second source region that has the first conductivity type in the second well implant region, and a JFET region that has the first conductivity type in between the first well implant region and the second well implant region, wherein the electric field concentration region has a higher doping concentration than the JFET region.

33. The semiconductor device of claim 32, further comprising a gate electrode on the semiconductor structure, the gate electrode vertically overlapping the JFET region and the first and second well implant regions.

34. The semiconductor device of claim 33, wherein the first well region includes a first lower corner that faces the JFET region and a second lower corner that faces away from the JFET region.

35. The semiconductor device of claim 34, wherein the second lower corner is sharper than the first lower corner.

36. (canceled)

37. The semiconductor device of claim 30, wherein a lower portion of the well contact region directly contacts the electric field concentration region.

38. The semiconductor device of claim 37, wherein the lower portion of the well contact region also directly contacts the first well region.

39. The semiconductor device of claim 30, wherein the electric field concentration region has a doping concentration that is greater than a doping concentration of the drift region.

40. The semiconductor device of claim 30, wherein the electric field concentration region extends deeper into the semiconductor structure than does the first well region.

41. The semiconductor device of claim 40, wherein the doping concentration of the electric field concentration region is less than a doping concentration of the source region.

42. The semiconductor device of claim 30, wherein the first well region extends deeper into the semiconductor structure than does the electric field concentration region, and the doping concentration of the electric field concentration region exceeds the doping concentration of the first well region.

43. A semiconductor device, comprising:
a semiconductor structure that comprises a drift region having a first conductivity type, a well region that has a second conductivity type on the drift region, a source region having the first conductivity type on the well region, and a well contact region that has the second conductivity type and a higher doping concentration than the well region on the well region,
wherein the well contact region extends further into the semiconductor structure than does the well region.

44. The semiconductor device of claim 43, further comprising a source metallization on an upper surface of the semiconductor structure, where an upper surface of the well contact region directly contacts the source metallization, wherein an upper surface of the semiconductor structure includes a recess that extends into the well contact region, and the source metallization extends into the recess.

45-46. (canceled)

47. The semiconductor device of claim 43, wherein, in a lateral cross-section of the semiconductor device, a lower portion of the well contact region includes a corner having an internal angle that is less than 90°.

48. The semiconductor device of claim 43, wherein the well region includes a first lower corner and the well contact region includes a second lower corner, where the second lower corner is a sharper corner than the first lower corner.

49-57. (canceled)

58. A semiconductor device, comprising:
a semiconductor structure that comprises a drift region having a first conductivity type, a well region that has a second conductivity type on the drift region, a source region having the first conductivity type on the well region, and a well contact region that has the second conductivity type and a higher doping concentration than the well region on the well region; and
a gate electrode on the semiconductor structure,
wherein a lower corner of the well contact region that directly contacts a portion of the semiconductor structure that has the first conductivity type is sharper than a lower corner of the well region that is farthest from the well contact region.

59. The semiconductor device of claim 58, wherein the lower portion of the well contact region directly contacts an electric field concentration region that has the first conductivity type, the electric field concentration region having a first conductivity type doping concentration that is greater than a doping concentration of the drift region.

60-63. (canceled)

64. The semiconductor device of claim 58, wherein, in a lateral cross-section of the semiconductor device, the lower portion of the well contact region includes a corner having an internal angle that is less than 90°.

65-66. (canceled)

67. The semiconductor device of claim 58, wherein the semiconductor device is configured so that during reverse blocking operations the electric field level at the second lower corner is higher than the electric field level at the first lower corner.

68-73. (canceled)
